(19) United States
(12) Patent Application Publication
(10) Pub. No.: US 2025/0123564 A1
(43) Pub. Date: Apr. 17, 2025

(54) RESIST COMPOSITION AND METHOD OF FORMING PATTERN BY USING THE SAME

(71) Applicants: Samsung Electronics Co., Ltd., Suwon-si (KR); Inha University Research and Business Foundation, Incheon (KR)

(72) Inventors: Chanjae AHN, Suwon-si (KR); Myungwoong KIM, Incheon (KR); Yoonhyun KWAK, Suwon-si (KR); Yunhee KO, Incheon (KR); Seungjun KIM, Incheon (KR)

(73) Assignees: Samsung Electronics Co., Ltd., Suwon-si (KR); Inha University Research and Business Foundation, Incheon (KR)

(21) Appl. No.: 18/770,083

(22) Filed: Jul. 11, 2024

(30) Foreign Application Priority Data
Jul. 17, 2023 (KR) 10-2023-0092474

(51) Int. Cl. G03F 7/039; C08F 212/14; G03F 7/00; G03F 7/038

(52) U.S. Cl. CPC G03F 7/039; C08F 212/24; G03F 7/038; G03F 7/70033

(57) ABSTRACT

Provided are a resist composition and a method of forming a pattern by using the same, the resist composition including a polymer including a first repeating unit represented by Formula 1, a photoacid generator, and an organic solvent:

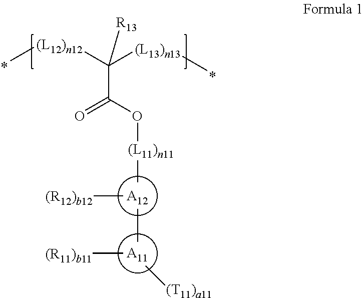

Formula 1 is as defined in the specification.

### CROSS-REFERENCE TO RELATED APPLICATION

This application is based on and claims priority under 35 U.S.C. § 119 to Korean Patent Application No. 10-2023-0092474, filed on Jul. 17, 2023 in the Korean Intellectual Property Office, the disclosure of which is incorporated by reference herein in its entirety.

### BACKGROUND

### 1. Field

The disclosure relates to a resist composition and a method of forming a pattern by using the same.

### 2. Description of the Related Art

In semiconductor manufacturing, resists of which physical properties change in response to light are used to form fine patterns. From among these resists, chemically amplified resists have been widely used. A chemically amplified resist enables patterning by changing the solubility of a base resin in a developing solution by reacting an acid, which is formed by a reaction between light and a photoacid generator, with the base resin.

In particular, in the case of using high-energy rays having relatively very high energy, such as extreme ultraviolet (EUV) radiation, the number of photons may be remarkably small even when light having the same energy is irradiated. Accordingly, there may be a demand for a resist composition that can act effectively even when used in a small amount and that can provide improved sensitivity and/or resolution.

### SUMMARY

Provided are a resist composition capable of providing improved sensitivity and/or improved resolution and a method of forming a pattern by using the resist composition.

Additional aspects will be set forth in part in the description which follows and, in part, will be apparent from the description, or may be learned by practice of the presented embodiments of the disclosure.

According to an embodiment of the disclosure, a resist composition may include a polymer including a first repeating unit represented by Formula 1, a photoacid generator, and an organic solvent.

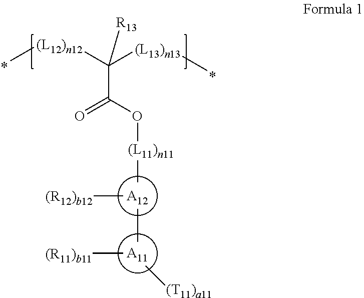

In Formula 1,
L₁₁ to L₁₃ may each independently be a single bond, O, S, C(═O), C(═O)O, OC(═O), C(═O)NH, NHC(═O), or a linear, branched, or cyclic C₁-C₃₀ divalent hydrocarbon group that optionally includes a heteroatom,
n11 to n13 may each independently be an integer from 1 to 4,
A₁₁ may be a C₆-C₃₀ aryl group or a C₁-C₃₀ heteroaryl group,
A₁₂ may be a C₁-C₃₀ divalent hydrocarbon group including at least two oxygens (O),
T₁₁ may be a nitro group or a C₁-C₂₀ alkoxy group,
a11 may be an integer from 1 to 5,
R₁₁ to R₁₃ may each independently be hydrogen, deuterium, a halogen, a cyano group, a hydroxy group, an amino group, a carboxylic acid group, a thiol group, an ester moiety, a sulfonate ester moiety, a carbonate moiety, a lactone moiety, a sultone moiety, a carboxylic anhydride moiety, or a linear, branched, or cyclic C₁-C₃₀ monovalent hydrocarbon group that optionally includes a heteroatom,
b11 and b12 may each independently be an integer from 1 to 10, and
* indicates a binding site to a neighboring atom.

According to an embodiment of the disclosure, a method of forming a pattern may include forming a resist film by applying the resist composition onto a substrate, exposing at least a portion of the resist film to high-energy rays to provide an exposed resist film, and developing the exposed resist film by using a developer solution.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a flowchart illustrating a pattern formation method according to an embodiment; and

FIGS. 2A to 2C are each a side cross-sectional view illustrating a pattern formation method according to an embodiment;

FIG. 3A is a diagram showing results of measuring a thickness of Polymer 1 according to exposure time;

FIG. 3B is a diagram showing results of measuring a thickness of Polymer 2 according to exposure time;

FIG. 4A is a diagram showing results of measuring a thickness of Comparison Polymer 1 according to exposure time; and

FIG. 4B is a diagram showing results of measuring a thickness of Comparison Polymer 2 according to exposure time.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

The disclosure may undergo various modifications and may have various embodiments. Accordingly, specific embodiments are illustrated in the drawings and described in detail in the detailed description. However, this is not intended to limit the disclosure to a specific embodiment, and should be understood to include all modifications, equivalents, or substitutes included in the spirit and technical scope of the disclosure. In describing the disclosure, when it is determined that a detailed description of related known technologies may make the gist of the disclosure unclear, the detailed description will be omitted.

The terms “first”, “second”, “third”, etc. may be used to describe various elements, but are used only for the purpose of distinguishing one element from another element, and the order or type of the elements are not limited.

Throughout this specification, a portion of a layer, film, region, plate, etc., described as being “on” or “above” another portion thereof may be positioned directly above, below, to the left or right of, while in contact, as well as above, below, to the left or light of, while in a non-contact

Singular expressions include plural expressions unless the context clearly dictates otherwise. Terms such as “include” or “have” are intended to indicate the presence of features, numbers, steps, operations, elements, parts, components, materials, or combinations thereof described in the specification unless otherwise stated, and it should be understood that the terms do not preclude the possibility of the presence or addition of one or more other features, numbers, steps, operations, elements, parts, components, materials, or combinations thereof.

Whenever a range of values is recited, that range includes all values that fall within that range, as if explicitly written out, and further includes the boundaries of the range. Accordingly, the range of “X” to “Y” includes all values between X and Y, including X and Y.

The term “Cₓ-C_{y}” as used herein refers to a case where the number of carbons constituting the substituent is x to y. For example, the term “C₁-C₆” refers to a case where the number of carbons constituting the substituent is 1 to 6, and the term “C₆-C₂₀” refers to a case where the number of carbons constituting the substituent is 6 to 20.

The term “monovalent hydrocarbon group” as used herein refers to a monovalent residue derived from an organic compound including carbon and hydrogen or a derivative of the organic compound, and examples thereof may include: a linear or branched alkyl group (e.g., a methyl group, an ethyl group, a propyl group, an isopropyl group, a butyl group, an isobutyl group, a sec-butyl group, a tert-butyl group, a pentyl group, a neopentyl group, a hexyl group, a heptyl group, a 2-ethylhexyl group, and a nonyl group); a monovalent saturated cyclic aliphatic hydrocarbon group (e.g., a cycloalkyl group) (e.g., a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a 1-adamantyl group, a 2-adamantyl group, a 1-adamantylmethyl group, a norbornyl group, a norbornylmethyl group, a tricyclotricyclodecanyl group, a tetracyclododecanyl, a tetracyclododecanylmethyl group, and a dicyclohexylmethyl group); a monovalent unsaturated aliphatic hydrocarbon group (e.g., an alkenyl group, an alkynyl group, and an allyl group); a monovalent unsaturated cyclic aliphatic hydrocarbon group (e.g., a cycloalkenyl group and a 3-cyclohexenyl group); an aryl group (e.g., a phenyl group, a 1-napthyl group, and a 2-napthyl group); an arylalkyl group (e.g., a benzyl group and a diphenylmethyl group); a heteroatom-containing monovalent hydrocarbon group (e.g., a tetrahydrofuranyl group, a methoxymethyl group, an ethoxy methyl group, a methylthiomethyl group, an acetamidemethyl group, a trifluoroethyl group, a (2-methoxyethoxy)methyl group, an acetoxymethyl group, a 2-carboxyl-1-cyclohexyl group, a 2-oxopropyl group, a 4-oxo-1-adamantyl group, and a 3-oxocyclohexyl group); or any combination thereof. Some hydrogens in these groups may be replaced by moieties containing heteroatoms such as oxygen, sulfur, nitrogen, or halogen atoms, or some carbons in these groups may be substituted by moieties containing heteroatoms such as oxygen, sulfur, or nitrogen. Accordingly, these groups may include hydroxy groups, cyano groups, carbonyl groups, carboxyl groups, ether linkages, ester linkages, ester sulfate linkages, carbonates, lactone rings, sultone rings, carboxylic acid anhydride moieties or haloalkyl moieties.

The term “divalent hydrocarbon group” as used herein refers to a divalent residue in which one hydrogen of the monovalent hydrocarbon group is replaced by a binding site to a neighboring atom. Examples of the divalent hydrocarbon group may include a linear or branched alkylene group, a cycloalkylene group, an alkenylene group, an alkynylene group, a cycloalkylene group, an arylene group, or a group in which some carbon atoms are replaced by a heteroatom.

The term “alkyl group” used herein refers to a linear or branched saturated aliphatic hydrocarbon monovalent group, and examples thereof include a methyl group, an ethyl group, a propyl group, an isobutyl group, a sec-butyl group, a ter-butyl group, a pentyl group, an iso-amyl group, a hexyl group, and the like. The term “alkylene group” as used herein refers to a linear or branched saturated aliphatic divalent hydrocarbon group, and examples thereof may include a methylene group, an ethylene group, a propylene group, a butylene group, an isobutyl group, and the like.

The term “halogenated alkyl group” as used herein refers to a group in which one or more hydrogen atoms of an alkyl group are substituted with halogen, and examples include may include CF₃ and the like.

The term “alkoxy group” used herein refers to a monovalent group represented by —OA₁₀₁, where A₁₀₁ is an alkyl group. Examples thereof include a methoxy group, an ethoxy group, an isopropyloxy group, and the like.

The term “alkylthio group” as used herein refers to a monovalent group represented by —SA₁₀₁, wherein A₁₀₁ is an alkyl group.

The term “halogenated alkyl group” as used herein refers to a group in which one or more hydrogen atoms of an alkoxy group are substituted with halogen, and examples thereof may include —OCF₃ and the like.

The term “halogenated alkylthio group” as used herein refers to a group in which one or more hydrogen atoms of an alkylthio group are substituted with halogen, and examples thereof may include —SCF₃ and the like.

The term “cycloalkyl group” used herein refers to a monovalent saturated hydrocarbon cyclic group, and examples thereof include monocyclic groups such as a cyclopropyl group, a cyclobutyl group, a cyclopentyl group, a cyclohexyl group, a cycloheptyl group, and the like, and polycyclic condensed cyclic groups such as a norbornyl group and an adamantyl group. The term “cycloalkylene group” used herein refers to a divalent saturated hydrocarbon cyclic group, and examples thereof include a cyclopentylene group, a cyclohexylene group, an adamantylene group, an adamantylmethylene group, a norbornylene group, a norbornylmethylene group, a tricyclodecanylene group, a tetracyclododecanylene a group, tetracyclododecanylmethylene group, a dicyclohexylmethylene group, and the like.

The term “cycloalkoxy group” used herein refers to a monovalent group represented by —OA₁₀₂, where A₁₀₂ is a cycloalkyl group. Examples thereof include a cyclopropoxy group, a cyclobutoxy group, and the like.

The term “cycloalkylthio group” as used herein refers to a monovalent group represented by —SA₁₀₂, wherein A₁₀₂ is a cycloalkyl group.

The term “heterocycloalkyl group” used herein refers to a group in which some carbon atoms of the cycloalkyl group are replaced by a moiety including a heteroatom, such as oxygen, sulfur, or nitrogen, and examples of the heterocycloalkyl group include an ether linking group, an ester linking group, a sulfonic ester linking group, a carbonate, a lactone ring, a sultone ring, or a carboxylic anhydride moiety. The term “heterocycloalkylene group” used herein refers to a group in which some carbon atoms of the cycloalkylene group are replaced by a moiety including a heteroatom, such as oxygen, sulfur, or nitrogen.

The term “heterocycloalkoxy group” as used herein refers to a monovalent group represented by —OA₁₀₃, wherein A₁₀₃ is a heterocycloalkyl group.

The term “alkenyl group” as used herein refers to a linear or branched unsaturated aliphatic monovalent hydrocarbon including one or more carbon-carbon double bond. The term “alkenylene group” as used herein refers to a linear or branched unsaturated aliphatic divalent hydrocarbon including one or more carbon-carbon double bonds.

The term “alkenyloxy group” as used herein refers to a monovalent group represented by —OA₁₀₄, wherein A₁₀₄ is an alkenyl group.

The term “cycloalkenyl group” as used herein refers to a monovalent unsaturated cyclic hydrocarbon group including one or more carbon-carbon double bonds. The term “cycloalkenylene group” as used herein refers to a divalent unsaturated cyclic hydrocarbon group including one or more carbon-carbon double bonds.

The term “cycloalkenyloxy group” as used herein refers to a monovalent group represented by —OA₁₀₅, wherein A₁₀₅ is an alkenyl group.

The term “heterocycloalkenyl group” as used herein refers to a group in which some carbon atoms of the cycloalkenylene group are replaced by a moiety including a heteroatom, such as oxygen, sulfur, or nitrogen. The term “heterocycloalkenylene group” used herein refers to a group in which some carbon atoms of the cycloalkenylene group are replaced by a moiety including a heteroatom, such as oxygen, sulfur, or nitrogen.

The term “heterocycloalkenyloxy group” as used herein refers to a monovalent group represented by —OA₁₀₆, wherein A₁₀₆ is a heterocycloalkenyl group.

The term “alkynyl group” as used herein refers to a linear or branched unsaturated aliphatic monovalent hydrocarbon including one or more carbon-carbon triple bonds.

The term “alkynyloxy group” as used herein refers to a monovalent group represented by —OA₁₀₇, wherein A₁₀₇ is an alkenyl group.

The term “aryl group” used herein refers to a monovalent group having a carbocyclic aromatic system, and examples include a phenyl group, a naphthyl group, an anthracenyl group, a phenanthrenyl group, a pyrenyl group, and a chrysenyl group.

The term “aryloxy group” as used herein refers to a monovalent group represented by —OA₁₀₈, wherein A₁₀₈ is an alkyl group.

The term “heteroaryl group” used herein refers to a monovalent group having a heterocyclic aromatic system, and examples thereof include a pyridinyl group, a pyrimidinyl group, a pyrazinyl group, and the like. The term “heteroarylene group” used herein refers to a divalent group having a heterocyclic aromatic system.

The term “heteroaryloxy group” as used herein refers to a monovalent group represented by —OA₁₀₉, wherein A₁₀₉ is a heteroaryl group.

The term “substituent” as used herein may include: deuterium, a halogen, a hydroxyl group, a cyano group, a nitro group, a carbonyl group, a carboxylic acid group, an amino group, an ether moiety, an ester moiety, a sulfonate ester moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio, a C₁-C₂₀ halogenated alkoxy group, a C₁-C₂₀ halogenated alkylthio, a C₃-C₂₀ cycloalkyl group, a C₅-C₂₀ cycloalkoxy group, a C₅-C₂₀ cycloalkylthio, a C₆-C₂₀ aryl group, a C₆-C₂₀ aryloxy group, a C₆-C₂₀ arylthio, a C₁-C₂₀ heteroaryl group, a C₁-C₂₀ heteroaryloxy group, or a C₁-C₂₀ heteroarylthio group;
a C₁-C₂₀ alkyl group, a C₁-C₂₀ halogenated alkyl group, a C₁-C₂₀ alkoxy group, a C₁-C₂₀ alkylthio, a C₁-C₂₀ halogenated alkoxy group, a C₁-C₂₀ halogenated alkylthio group, a C₃-C₂₀ cycloalkyl group, a C₅-C₂₀ cycloalkoxy group, a C₅-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, or a C₁-C₂₀ heteroarylthio, each substituted with deuterium, a halogen, a hydroxyl group, a cyano group, a nitro group, a carbonyl group, a carboxylic acid group, an amino group, an ether moiety, an ester moiety, a sulfonate ester moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, a C₁-C₂₀ heteroarylthio group, or any combination thereof; and any combination thereof.

Hereinafter, an embodiment according to the disclosure will be described in detail with reference to the drawings, and in the description with reference to the drawings, substantially the same or corresponding elements are denoted with the same reference numerals, and overlapping descriptions thereof will be omitted. Regarding the drawings, the thickness is shown enlarged to clearly express the various layers and regions. Also, in the drawings, the thicknesses of some layers and regions are exaggerated for convenience of description. On the other hand, the embodiments described below are merely illustrative, and various modifications can be made on these embodiments.

### [Polymer]

A polymer according to one or more embodiments may include a first repeating unit represented by Formula 1:

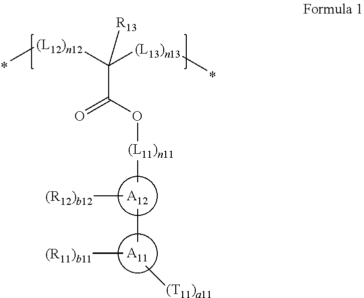

wherein, in Formula 1, L₁₁ to L₁₃ may each independently be a single bond; O; S; C(═O); C(═O)O; OC(═O); C(═O)NH; NHC(═O); or a linear, branched, or cyclic C₁-C₃₀ divalent hydrocarbon group that optionally includes a heteroatom.

In an embodiment, L₁₁ to L₁₃ may each independently be: a single bond; O; S; C(═O); C(═O)O; OC(═O); C(═O)NH; NHC(═O); a substituted or unsubstituted C₁-C₃₀ alkylene group; a substituted or unsubstituted C₃-C₃₀ cycloalkylene group; a substituted or unsubstituted C₃-C₃₀ heterocycloalkylene group; a substituted or unsubstituted C₂-C₃₀ alkenylene group; a substituted or unsubstituted C₃-C₃₀ cycloalkenylene group; a substituted or unsubstituted C₃-C₃₀ heterocycloalkenylene group; a substituted or unsubstituted C₆-C₃₀ arylene group; or a substituted or unsubstituted C₁-C₃₀ heteroarylene group.

In an embodiment, L₁₁ to L₁₃ in Formula 1 may each independently be: a single bond; O; C(═O); C(═O)O; OC(═O); or a C₁-C₂₀ alkylene group, a C₃-C₂₀ cycloalkylene group, a C₃-C₂₀ heterocycloalkylene group, a phenylene group, or a naphthylene group, each unsubstituted or substituted with deuterium, a halogen, a C₁-C₁₀ alkyl group, a C₁-C₁₀ halogenated alkyl group, a C₁-C₁₀ alkoxy group, a phenyl group, a naphthyl group, or any combination thereof.

In Formula 1, n11 to n13 may represent the number of repetition of L₁₁ to the number of repetition of L₁₃, respectively. When n11 is 2 or greater, two or more of L₁₁ may be identical to or different from each other, when n12 is 2 or greater, two or more of L₁₂ may be identical to or different from each other, and when n13 is 2 or greater, two or more of L₁₃ may be identical to or different from each other.

In Formula 1, n11 to n13 may each independently be an integer from 1 to 4.

In an embodiment, each of n11 to n13 may be 1.

In Formula 1, A₁₁ may be a C₆-C₃₀ aryl group or a C₁-C₃₀ heteroaryl group.

In an embodiment, A₁₁ may be a benzene group, a naphthalene group, a phenanthrene group, an anthracene group, a pyrene group, a chrysene group, or an indene group.

In an embodiment, a moiety represented by

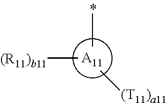

in Formula 1 may be a group represented by Formula 1A:

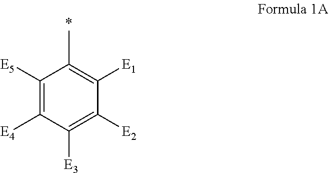

wherein, in Formula 1A,
E₁ to E₅ may each independently be: hydrogen; deuterium; a halogen; a cyano group; a hydroxy group; an amino group; a nitro group; a carboxylic acid group; a thiol group; an ester moiety; a sulfonate ester moiety; a carbonate moiety; a lactone moiety; a sultone moiety; a carboxylic anhydride moiety; or a linear, branched, or cyclic C₁-C₃₀ monovalent hydrocarbon group that optionally includes a heteroatom,
at least one of E₁ to E₅ may be a nitro group or a C₁-C₂₀ alkoxy group, and
* indicates a binding site to a neighboring atom.

For example, in Formula 1A,
i) E₁ may be a nitro group, and each of E₂ to E₄ may be hydrogen;
ii) E₁ may be a nitro group, each of E₂ and E₅ may be hydrogen, and E₃ and E₄ may each independently be a C₁-C₁₀ alkoxy group;
ii) E₁ may be a nitro group, each of E₂ and E₅ may be hydrogen, and E₄ and E₅ may each independently be a C₁-C₁₀ alkoxy group; or
iv) E₁ and E₄ may each independently be a C₁-C₁₀ alkoxy group, and E₂, E₃, and E₅ may each be hydrogen.

In Formula 1, A₁₂ may be a C₁-C₃₀ divalent hydrocarbon group including at least two O.

In an embodiment, A₁₂ may have an acetal structure within a ring. For example, A₁₂ may be a 1,3-dioxane group or a 1,3-dioxolane group.

In an embodiment, a moiety represented by

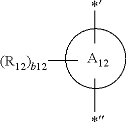

in Formula 1 may be a group represented by Formula 1B:

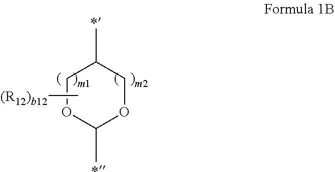

wherein, in Formula 1B,
m1 and m2 may each independently be an integer from 0 to 5,
*′ indicates a binding site to L₁₁ in Formula 1,
*″ indicates a binding site to A₁₁ in Formula 1, and
R₁₂ and b12 are each as defined in Formula 1.

For example, in Formula 1B, i) m1 may be 1, and m2 may be 0; ii) each of m1 and m2 may be 1; or iii) m1 may be 2, and m2 may be 0.

In an embodiment, a moiety represented by

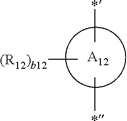

in Formula 1 may be a group represented by one of Formulae 1B-1 to 1B-3:

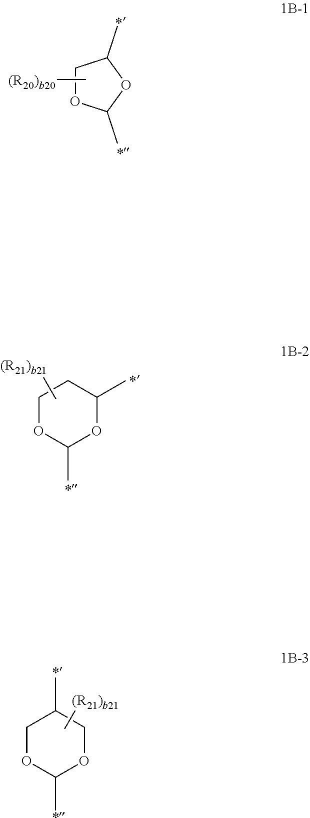

wherein, in Formulae 1B-1 to 1B-3,
R₂₀ and R₂₁ are each independently as defined for R₁₂ in Formula 1,
b20 may be an integer from 1 to 4,
b21 may be an integer from 1 to 6,
*′ indicates a binding site to L₁₁ in Formula 1, and
*″ indicates a binding site to A₁₁ in Formula 1.

In Formula 1, T₁₁ may be a nitro group or a C₁-C₂₀ alkoxy group.

In Formula 1, a11 may be an integer from 1 to 5. When a11 is 2 or more, two or more of R₁₁ may be identical to or different from each other.

In an embodiment, when a11 is 1, T₁₁ may be a nitro group or a C₁-C₂₀ alkoxy group.

In an embodiment, when a11 is 2, each of T₁₁ may be a C₁-C₂₀ alkoxy group.

In an embodiment, when a11 is 3, one T₁₁ may be a nitro group, and each of the remaining two T₁₁(s) may be a C₁-C₂₀ alkoxy group.

In Formula 1, R₁₁ to R₁₃ may each independently be: hydrogen; deuterium; a halogen; a cyano group; a hydroxy group; an amino group; a carboxylic acid group; a thiol group; an ester moiety; a sulfonate ester moiety; a carbonate moiety; a lactone moiety; a sultone moiety; a carboxylic anhydride moiety; or a linear, branched, or cyclic C₁-C₃₀ monovalent hydrocarbon group that optionally includes a heteroatom.

In addition, two or a plurality of R₁₁ adjacent to each other may optionally be bonded to each other to form a condensed ring, and two or a plurality of R₁₂ adjacent to each other may optionally be bonded to each other to form a condensed ring.

In an embodiment, R₁₁ to R₁₃ may each independently be: hydrogen; deuterium; a halogen; a cyano group; a hydroxy group; an amino group; a carboxylic acid group; a thiol group; or a C₁-C₂₀ alkyl group, a C₅-C₂₀ cycloalkyl group, or a C₆-C₂₀ aryl group, each unsubstituted or substituted with deuterium, a halogen, a cyano group, a hydroxy group, an amino group, a carboxylic acid group, a thiol group, an ester moiety, a sulfonate ester moiety, a carbonate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₅-C₂₀ cycloalkyl group, a C₃-C₂₀ cycloalkoxy group, a C₆-C₂₀ aryl group, or any combination thereof.

In an embodiment, R₁₁ may be hydrogen, deuterium, a halogen, CH₃, CH₂F, CHF₂, CF₃, CH₂CH₃, CHFCH₃, CHFCH₂F, CHFCHF₂, CHFCF₃, CF₂CH₃, CF₂CH₂F, CF₂CHF₂, or CF₂CF₃.

In an embodiment, R₁₂ and R₁₃ may each independently be hydrogen or deuterium.

In Formula 1, b11 and b12 may each independently be an integer from 1 to 10.

In Formula 1, * indicates a binding site to a neighboring atom.

In an embodiment, the first repeating unit may be represented by Formula 1-1:

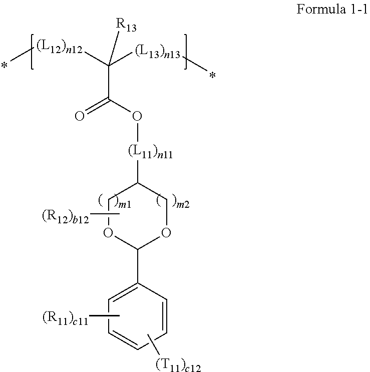

wherein, in Formula 1-1,
m1 and m2 may each independently be an integer from 0 to 5,
L₁₁ to L₁₃, n11 to n13, T₁₁, R₁₁ to R₁₃, and b12 are each as defined in Formula 1,
c11 and c12 may each independently be an integer from 1 to 4, and
* indicates a binding site to a neighboring atom.

In an embodiment, the first repeating unit may be selected from Group I:

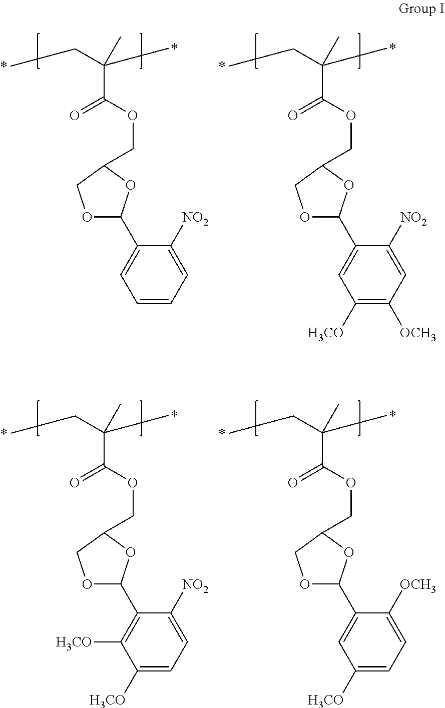

In an embodiment, the polymer may further include at least one of a second repeating unit represented by Formula 2 and a third repeating unit represented by Formula 3:

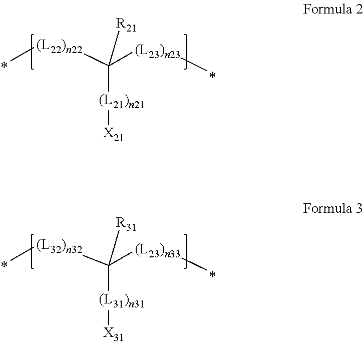

wherein, in Formulae 2 and 3,
L₂₁ to L₂₃ and L₃₁ to Las may each independently be: a single bond; O; S; C(═O); C(═O)O; OC(═O); C(═O)NH; NHC(═O); or a linear, branched, or cyclic C₁-C₃₀ divalent hydrocarbon group that optionally includes a heteroatom,
n21 to n23 and n31 to n33 may each independently be an integer from 1 to 4,
R₂₁ and R₃₁ may each independently be: hydrogen; deuterium; a halogen; a cyano group; a hydroxy group; an amino group; a carboxylic acid group; a thiol group; an ester moiety; a sulfonate ester moiety; a carbonate moiety; a lactone moiety; a sultone moiety; a carboxylic anhydride moiety; or a linear, branched, or cyclic C₁-C₃₀ monovalent hydrocarbon group that optionally includes a heteroatom,
X₂₁ may be a non-acid labile group,
X₃₁ may be an acid labile group, and
* indicates a binding site to a neighboring atom.

In an embodiment, L₂₁ to L₂₃ and L₃₁ to L₃₃ may each independently be: a single bond; O; S; C(═O); C(═O)O; OC(═O); C(═O)NH; NHC(═O); a substituted or unsubstituted C₁-C₃₀ alkylene group; a substituted or unsubstituted C₃-C₃₀ cycloalkylene group; a substituted or unsubstituted C₃-C₃₀ heterocycloalkylene group; a substituted or unsubstituted C₂-C₃₀ alkenylene group; a substituted or unsubstituted C₃-C₃₀ cycloalkenylene group; a substituted or unsubstituted C₃-C₃₀ heterocycloalkenylene group; a substituted or unsubstituted C₆-C₃₀ arylene group; or a substituted or unsubstituted C₁-C₃₀ heteroarylene group.

In an embodiment, L₂₁ to L₂₃ and L₃₁ to L₃₃ may each independently be: a single bond; O; C(═O); C(═O)O; OC(═O); or a C₁-C₂₀ alkylene group, a C₃-C₂₀ cycloalkylene group, a C₃-C₂₀ heterocycloalkylene group, a phenylene group, or a naphthylene group, each unsubstituted or substituted with deuterium, a halogen, a C₁-C₁₀ alkyl group, a C₁-C₁₀ halogenated alkyl group, a C₁-C₁₀ alkoxy group, a phenyl group, a naphthyl group, or any combination thereof.

In Formulae 2 and 3, n21 to n23 and n31 to n33 represent the number of repetitions of L₂₁ to L₂₃ and the number of repetitions of L₃₁ to L₃₃, respectively.

When n21 is 2 or greater, two or more of L₂₁ may be identical to or different from each other, when n22 is 2 or greater, two or more of L₂₂ may be identical to or different from each other, and when n23 is 2 or greater, two or more of L₂₃ may be identical to or different from each other. When n31 is 2 or greater, two or more of L₃₁ may be identical to or different from each other, when n32 is 2 or greater, two or more of L₃₂ may be identical to or different from each other, and when n33 is 2 or greater, two or more of L₃₃ may be identical to or different from each other.

In an embodiment, R₂₁ and R₃₁ may each independently be: hydrogen; deuterium; a halogen; a cyano group; a hydroxy group; an amino group; a carboxylic acid group; a thiol group; or a C₁-C₂₀ alkyl group, a C₅-C₂₀ cycloalkyl group, or a C₆-C₂₀ aryl group, each unsubstituted or substituted with deuterium, a halogen, a cyano group, a hydroxy group, an amino group, a carboxylic acid group, a thiol group, an ester moiety, a sulfonate ester moiety, a carbonate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₃-C₂₀ cycloalkyl group, a C₅-C₂₀ cycloalkoxy group, a C₆-C₂₀ aryl group, or any combination thereof.

For example, R₂₁ and R₃₁ may each independently be hydrogen, deuterium, a halogen, CH₃, CH₂F, CHF₂, CF₃, CH₂CH₃, CHFCH₃, CHFCH₂F, CHFCHF₂, CHFCF₃, CF₂CH₃, CF₂CH₂F, CF₂CHF₂, or CF₂CF₃.

In an embodiment, X₂₁ in Formula 2 may be: hydrogen; a halogen; a cyano group; a hydroxy group; a carboxylic acid group; a thiol group; an amino group; or a linear, branched, or cyclic C₁-C₃₀ monovalent hydrocarbon group that includes one or more polar moieties selected from halogen, a cyano group, a hydroxy group, a thiol group, a carboxylic acid group, O, C═O, C(═O)O, OC(═O), S(═O)O, OS(═O), a lactone moiety, a sultone moiety, and a carboxylic anhydride moiety.

In an embodiment, X₂₁ in Formula 2 may be: hydrogen; a hydroxy group; or a linear, branched, or cyclic C₁-C₃₀ monovalent hydrocarbon group including O.

In an embodiment, the polymer may further include the second repeating unit and the second repeating unit may be represented by Formula 2-1:

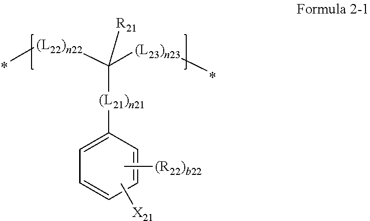

wherein, in Formula 2-1,
L₂₁ to L₂₃, n21 to n23, R₂₁, and X₂₁ are each as defined in Formula 2,
R₂₂ may be: hydrogen; deuterium; a halogen; a cyano group; a hydroxy group; a C₁-C₂₀ alkoxy group; or a linear, branched, or cyclic C₁-C₂₀ monovalent hydrocarbon group that optionally includes a heteroatom,
b22 may be an integer from 1 to 4, and
* indicates a binding site to a neighboring atom.

In an embodiment, the second repeating unit may be selected from Group II:

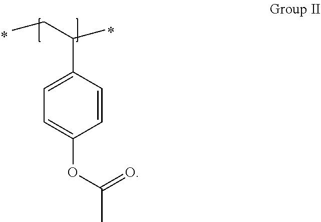

In an embodiment, X₃₁ in Formula 3 may be represented by one of Formulae 6-1 to 6-12:

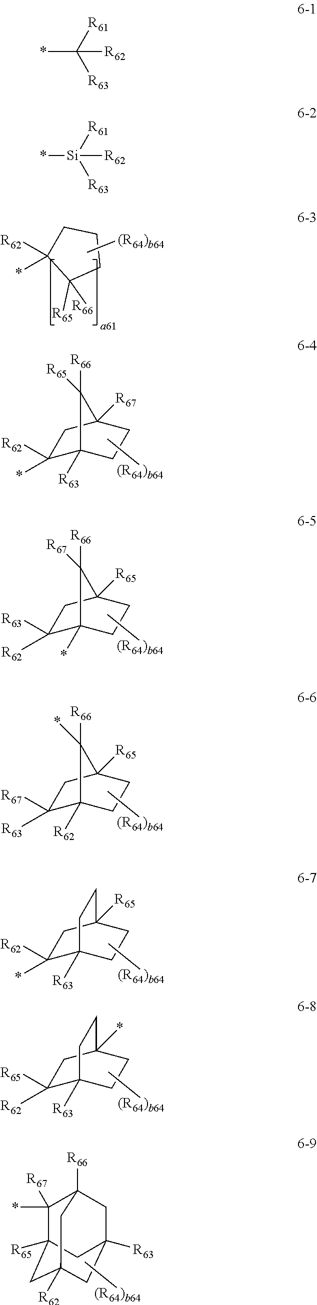

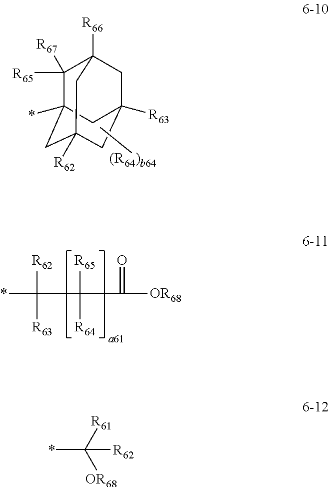

wherein, in Formulae 6-1 to 6-12,
a61 may be an integer from 0 to 6,
R₆₁ to R₆₇ may each independently be hydrogen or a linear, branched, or cyclic C₁-C₂₀ monovalent hydrocarbon group that optionally includes a heteroatom,
R₆₈ may be a linear, branched, or cyclic C₁-C₂₀ monovalent hydrocarbon group that optionally includes a heteroatom,
two adjacent of R₆₁ to R₆₈ may optionally be bonded to each other to form a ring,
b64 may be an integer from 0 to 6, and
* indicates a binding site to a neighboring atom.

For example, X₃₁ in Formula 3 may be selected from Formulas 6-4 to 6-10.

For example, when an adjacent two groups among R₆₁ to R₆₈ in Formula 3 are optionally bonded to form a ring, the ring may be formed via a linker such as O, a carboxyl group (C═O), an ester group (COO), or the like.

In an embodiment, the polymer may include the third repeating unit and the third repeating unit may be represented by Formula 3-1:

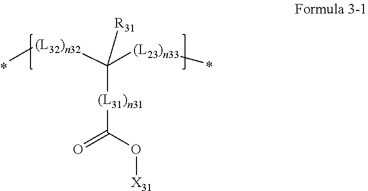

wherein, in Formula 3-1,
L₃₁ to L₃₃, n31 to n33, and R₃₁ are each as defined in Formula 3, and
* indicates a binding site to a neighboring atom.

In an embodiment, the third repeating unit may be selected from Group III:

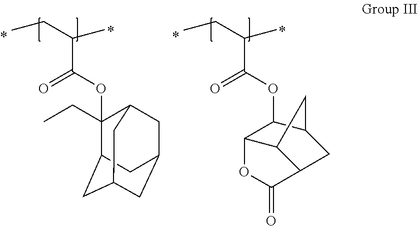

In one or more embodiments, the polymer may include the third repeating unit represented by Formula 3, and may further include a fourth repeating unit represented by Formula 3, wherein the third repeating unit and the fourth repeating unit may be different from each other.

In one or more embodiments, the polymer may include the second repeating unit represented by Formula 2, the third repeating unit represented by Formula 3, and a fourth repeating unit represented by Formula 3, wherein the third repeating unit and the fourth repeating unit may be different from each other.

In an embodiment, the polymer may include the first repeating unit in an amount in a range of about 1 mol % to about 100 mol %, about 5 mol % to about 100 mol %, or about 10 mol % to about 100 mol %.

In one or more embodiments, the polymer may include (or consist of) the first repeating unit.

In an embodiment, the polymer may include the second repeating unit in an amount in a range of about 0 mol % to about 99 mol %, about 1 mol % to about 99 mol %, or about 10 mol % to about 90 mol %.

In an embodiment, the polymer may include the third repeating unit in an amount in a range of about 0 mol % to about 99 mol %, about 1 mol % to about 99 mol %, or about 10 mol % to about 90 mol %.

In an embodiment, the polymer may include (or consist of) the first repeating unit and the second repeating unit. In one or more embodiments, the polymer may include the first repeating unit in an amount in a range of about 1 mol % to about 99 mol % or about 10 mol % to about 90 mol %, and the second repeating unit in an amount in a range of about 1 mol % to about 99 mol % or about 10 mol % to about 90 mol %.

In an embodiment, the polymer may include (or consist of) the first repeating unit and the third repeating unit. In one or more embodiments, the polymer may include the first repeating unit in an amount in a range of about 1 mol % to about 99 mol % or about 10 mol % to about 90 mol %, and the third repeating unit in an amount in a range of about 1 mol % to about 99 mol % or about 10 mol % to about 90 mol %.

In an embodiment, the polymer may include (or consist of) the first repeating unit, the second repeating unit, and the third repeating unit. In one or more embodiments, the polymer may include the first repeating unit in an amount in a range of about 1 mol % to about 98 mol % or about 5 mol % to about 90 mol %, the second repeating unit in an amount in a range of about 1 mol % to about 98 mol % or about 5 mol % to about 90 mol %, and the third repeating unit in an amount in a range of about 1 mol % to about 98 mol % or about 5 mol % to about 90 mol %.

In an embodiment, the polymer may include (or consist of) the first repeating unit, the third repeating unit, and the fourth repeating unit. In one or more embodiments, the polymer may include the first repeating unit in an amount in a range of about 1 mol % to about 98 mol % or about 5 mol % to about 90 mol %, the third repeating unit in an amount in a range of about 1 mol % to about 98 mol % or about 5 mol % to about 90 mol %, and the fourth repeating unit in an amount in a range of about 1 mol % to about 98 mol % or about 5 mol % to about 90 mol %.

In an embodiment, the polymer may include (or consist of) the first repeating unit, the second repeating unit, the third repeating unit, and the fourth repeating unit. For example, the polymer may include the first repeating unit in an amount in a range of about 1 mol % to about 98 mol % or about 5 mol % to about 90 mol %, the second repeating unit in an amount in a range of about 1 mol % to about 98 mol % or about 5 mol % to about 90 mol %, the third repeating unit in an amount in a range of about 1 mol % to about 98 mol % or about 5 mol % to about 90 mol %, and the fourth repeating unit in an amount in a range of about 1 mol % to about 98 mol % or about 5 mol % to about 90 mol %.

The polymer may have a weight average molecular weight (Mw) in a range of about 1,000 to 500,000, for example, about 3,000 to about 100,000 or about 5,000 to about 50,000, wherein the weight average molecular weight is measured by gel permeation chromatography using a tetrahydrofuran solvent and polystyrene as a standard material.

The polymer may have polydispersity index (PDI: Mw/Mn) in a range of about 1.0 to about 3.0, for example, about 1.0 to about 2.5. When the PDI of the polymer is satisfied within the ranges above, there is a less chance of remaining foreign substances on a pattern, or deterioration of a pattern profile may be minimized. Accordingly, the resist composition including the polymer may be more suitable for forming fine patterns.

Typically, since EUV (13.5 nm) has a lower number of photons compared to ArF immersion light sources, the lower the exposure dose is, noise increases significantly at the boundary area between the area exposed by the EUV light source and the unexposed area that is not exposed. In the case of a lithography process using an EUV light source, in order to compensate for this, a larger amount of a photoacid generator may be used compared to a lithography process using another light source having the same amount of light. However, when the resist composition includes a high content of a photoacid generator, the glass transition temperature (Tg) of the base resin may change and thermal stability thereof may deteriorate. In addition, the resolution of resist patterns formed due to a photoacid generator remaining during a lithography process using an EUV light source, may deteriorate.

The polymer including the first repeating unit represented by Formula 1 may generate electrons by high-energy rays, especially EUV light sources, whereas the photoacid generator may not directly absorb EUV light sources. In detail, the polymer including the first repeating unit represented by Formula 1 may be ionized by high-energy rays to generate radical cations and electrons. Subsequently, when the electrons loss some of the energy by surrounding molecules, the resulting electrons may then react with a photoacid generator to produce acids from the photoacid generator.

That is, the polymer including the first repeating unit represented by Formula 1 may have considerably high sensitivity to light because the polarity of the polymer may be changed not only by the acid produced by light during light exposure, but also directly by light. Therefore, a resist composition including the polymer may be able to produce acids even at relatively low light doses, thereby improving the resolution of resist patterns obtained therefrom.

### [Resist Composition]

Another aspect provides a resist composition including the polymer, a photoacid generator, and an organic solvent. The resist composition may have, for example, improved developability and/or improved resolution.

The solubility of the resist composition in a developing solution is changed by exposure to high-energy rays. The resist composition may be a positive resist composition corresponding to a case where an exposed portion of the resist film is dissolved and removed to form a positive resist pattern, or a negative resist composition corresponding to a case where an unexposed portion of the resist film is dissolved and removed to form a negative resist pattern. In addition, the resist composition according to an embodiment may be used for an alkali developing process using an alkali developing solution for a developing process in forming a resist pattern, or may be used for a solvent developing process using a developing solution containing an organic solvent for the developing process (hereinafter referred to as an organic developing solution).

The polymer may be included in an amount of about 0.1 parts by weight to about 10 parts by weight, based on 100 parts by weight of the resist composition. For example, the amount of the polymer may be, based on 100 parts by weight of the resist composition, about 0.05 parts by weight to about 70 parts by weight, about 0.1 parts by weight to about 50 parts by weight, about 0.5 parts by weight to about 40 parts by weight, about 1 part by weight to about 20 parts by weight, or about 2 parts by weight to about 10 parts by weight.

When the amount of the polymer is satisfied within these ranges, the polymer may exhibit sensitizer functions at an appropriate level, and formation of foreign particles may be reduced due to loss of any performance, e.g., a decrease in sensitivity and/or a lack of solubility.

Regarding the polymer as described above, the photoacid generator, the organic solvent, and optional components such as a quencher, a base resin, or the like contained as necessary will be described below.

### <Photoacid Generator>

The photoacid generator may be any compound capable of generating an acid when exposed to high-energy rays such as UV, DUV, EB, EUV, X-rays, α-rays, and γ-rays.

The photoacid generator may include a sulfonium salt, an iodonium salt, or a combination thereof.

In an embodiment, the photoacid generator may be represented by Formula 7:

B₇₁_{⁺}A₇₁_{^{−}} Formula 7
wherein, in Formula 7,
B₇₁_{⁺} may be represented by Formula 7A, A₇₁ may be represented by one of Formulae 7B to 7D, and
B₇₁_{⁺} and A₇₁ may optionally be linked to each other via a carbon-carbon covalent bond:

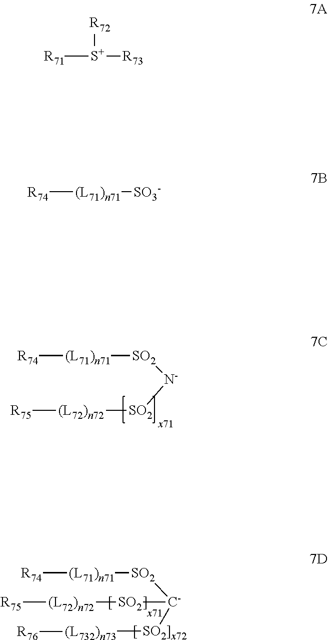

wherein, in Formulae 7A to 7D,
L₇₁ to L₇₃ may each independently be a single bond or CRR′,
R and R′ may each independently be hydrogen, deuterium, a halogen, a cyano group, a hydroxy group, a C₁-C₃₀ alkyl group, a C₁-C₃₀ halogenated alkyl group, a C₁-C₃₀ alkoxy group, a C₃-C₃₀ cycloalkyl group, or a C₃-C₃₀ cycloalkoxy group,
n71 to n73 may each independently be 1, 2, or 3,
x71 and x72 may each independently be 0 or 1,
R₇₁ to R₇₃ may each independently be a linear, branched, or cyclic C₁-C₃₀ monovalent hydrocarbon group that optionally includes a heteroatom,
an adjacent two groups among R₇₁ to R₇₃ may optionally be bonded to each other to form a condensed ring, and
R₇₄ to R₇₆ may each independently be: hydrogen; a halogen; or a linear, branched, or cyclic C₁-C₃₀ monovalent hydrocarbon group that optionally includes a heteroatom.

For example, in Formula 7, B₇₁_{⁺} may be represented by Formula 7A, and A₇₁_{^{−}} may be represented by Formula 7B. In detail, each of R₇₁ to R₇₃ in Formula 7 may be a phenyl group.

The photoacid generator may be included in an amount in a range of about 0.01 parts by weight to about 40 parts by weight, about 0.1 parts by weight to about 40 parts by weight, or about 0.1 parts by weight to about 20 parts by weight, based on 100 parts by weight of the polymer. When the amount of the photoacid generator is satisfied within the ranges above, proper resolution may be achieved, and problems related to foreign particles after development or during stripping may be reduced.

One type of the photoacid generator may be used, or a combination of two or more different types of the photoacid generator may be used.

### <Organic Solvent>

The organic solvent included in the resist composition may not be particularly limited as long as it is capable of dissolving or dispersing a polymer, a photoacid generator, and optional components such as a quencher contained as necessary. One type of the organic solvent may be used, or a combination of two or more different types of the organic solvent may be used. Also, a mixed solvent in which water and an organic solvent are mixed may be used.

Examples of the organic solvent may include an alcohol-based solvent, an ether-based solvent, a ketone-based solvent, an amide-based solvent, an ester-based solvent, a sulfoxide-based solvent, a hydrocarbon-based solvent, and the like.

Examples of the alcohol-based solvent may include: a monoalcohol-based solvent, such as methanol, ethanol, n-propanol, isopropanol, 1-methoxy-2-propanol, 1-ethoxy-2-propanol, n-butanol, isobutanol, sec-butanol, tert-butanol, n-pentanol, isopentanol, 2-methylbutanol, sec-pentanol, tert-pentanol, 3-methoxybutanol, 3-methyl-3-methoxybutanol, n-hexanol, 2-methylpentanol, sec-hexanol, 2-ethylbutanol, 4-methyl-2-pentanol (MIBC), sec-heptanol, 3-heptanol, n-octanol, 2-ethylhexanol, sec-octanol, n-nonylalcohol, 2,6-dimethyl-4-heptanol, n-decanol, sec-undecyl alcohol, trimethylnonyl alcohol, sec-tetradecyl alcohol, sec-heptadecyl alcohol, furfuryl alcohol, phenol, cyclohexanol, methylcyclohexane alcohol, 3,3,5-trimethylcyclohexanol, benzyl alcohol, diacetone alcohol, and the like; a polyhydric alcohol solvent, such as ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, and tripropylene glycol; and polyhydric alcohol-containing ether solvents such as ethylene glycol monomethyl ether, ethylene glycol monoethyl ether, ethylene glycol monopropyl ether, ethylene glycol monobutyl ether, ethylene glycol monohexyl ether, ethylene glycol monophenyl ether, ethylene glycol mono-2-ethylbutyl ether, diethylene glycol monomethyl ether, diethylene glycol monoethyl ether, diethylene glycol monopropyl ether, diethylene glycol monobutyl ether, diethylene glycol monohexyl ether, diethylene glycol dimethyl ether, propylene glycol monomethyl ether, propylene glycol dimethyl ether, propylene glycol monoethyl ether, propylene glycol monopropyl ether, propylene glycol monobutyl ether, dipropylene glycol monomethyl ether, dipropylene glycol monoethyl ether, dipropylene glycol monopropyl ether, and the like.

Examples of the ether-based solvent may include: a dialkyl ether-based solvent, such as diethyl ether, dipropyl ether, dibutyl ether, and the like; a cyclic ether-based solvent, such as tetrahydrofuran, tetrahydropyran, and the like; an aromatic ring-containing ether-based solvent, such as diphenyl ether, anisole, and the like; and the like.

Examples of the ketone-based solvent may include: a chain ketone-based solvent, such as acetone, methylethyl ketone, methyl-n-propyl ketone, methyl-n-butyl ketone, methyl-n-pentyl ketone, diethyl ketone, methyl isobutyl ketone, 2-heptanone, ethyl-n-butyl ketone, methyl-n-hexyl ketone, diisobutyl ketone, trimethylnonanone, and the like; a cyclic ketone solvent, such as cyclopentanone, cyclohexanone, cycloheptanone, cyclooctanone, methylcyclohexanone, and the like; 2,4-pentanedione; acetonylacetone; acetphenone; and the like.

Examples of the amide-based solvent are: a cyclic amide-based solvent, such as N,N′-dimethylimidazolidinone, N-methyl-2-pyrrolidone, and the like; a chain amide-based solvent, such as N-methylformamide, N,N-dimethylformamide, N,N-diethylformamide, acetamide, N-methylacetamide, N,N-dimethylacetamide, N-methylpropionamide, and the like; and the like.

Examples of ester solvent may include: an acetate ester solvent, such as methyl acetate, ethyl acetate, n-propyl acetate, isopropyl acetate, n-butyl acetate, isobutyl acetate, sec-butyl acetate, T-butyl acetate, n-pentyl acetate, isopentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, and the like; a polyhydric alcohol-containing ether carboxylate solvent, such as ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, and the like; a lactone solvent, such as γ-butyrolactone and δ-valerolactone; carbonate solvents such as dimethyl carbonate, diethyl carbonate, ethylene carbonate, and propylene carbonate; lactate ester solvents such as methyl lactate, ethyl lactate, n-butyl lactate, n-amyl lactate, and the like; glycoldiacetate; methoxytriglycol acetate; ethyl propionate; n-butyl propionate; isoamyl propionate; diethyloxalate; di-n-butyloxalate; methyl acetoacetate; ethyl acetoacetate; diethyl malonate; dimethyl phthalate; diethyl phthalate; and the like.

Examples of the sulfoxide-based solvent may include dimethyl sulfoxide, diethyl sulfoxide, and the like.

Examples of the hydrocarbon-based solvent may include: an aliphatic hydrocarbon-based solvent, such as n-pentane, isopentane, n-hexane, isohexane, n-heptane, isoheptane, 2,2,4-trimethyl pentane, n-octane, isooctane, cyclohexane, methylcyclohexane, and the like; and an aromatic hydrocarbon-based solvent, such as benzene, toluene, xylene, mesitylene, ethyl benzene, trimethyl benzene, methylethyl benzene, n-propyl benzene, isopropyl benzene, diethyl benzene, isobutyl benzene, triethyl benzene, diisopropyl benzene, n-amylnaphthalene, and the like.

In an embodiment, the organic solvent may be selected from an alcohol-based solvent, an amide-based solvent, an ester-based solvent, a sulfoxide-based solvent, and any combination thereof. In one or more embodiments, the organic solvent may be selected from propylene glycol monomethyl ether, propylene glycol monoethyl ether, propylene glycol monomethyl ether acetate, N-methyl-2-pyrrolidone, N,N-dimethylacetamide, ethyl lactate, dimethyl sulfoxide, and any combination thereof.

In an embodiment, when an acetal-type acid labile group is used, the organic solvent may further include alcohol having a high boiling point, such as diethylene glycol, propylene glycol, glycerol, 1,4-butanediol, or 1,3-butanediol, to accelerate a deprotection reaction of acetal.

The organic solvent may be used in an amount in a range of about 200 parts by weight to about 5,000 parts by weight, about 500 parts by weight to about 4,000 parts by weight, or about 1,000 parts by weight to about 3,000 parts by weight, based on 100 parts by weight of the polymer.

### <Quencher>

The resist composition may further include a quencher.

The quencher may be a salt that generates an acid with weaker acidity than the acid generated from the photoacid generator.

The quencher may include an ammonium salt, a sulfonium salt, an iodonium salt, or a combination thereof.

In an embodiment, the quencher may be represented by Formula 8:

B₈₁_{⁺}A₈₁_{^{−}} Formula 8

wherein, in Formula 8,
B₈₁_{⁺} may be represented by one of Formulae 8A to 8C, and A₈₁_{^{−}} may be represented by one of Formulae 8D to 8F, and
B₈₁_{⁺} and A₈₁ may optionally be linked to each other via a carbon-carbon covalent bond:

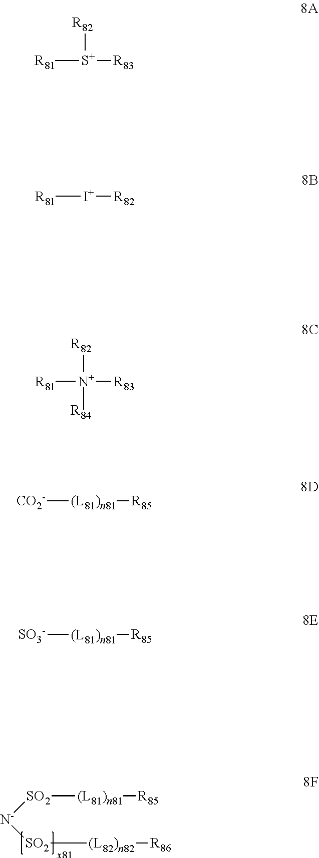

wherein, in Formulae 8A to 8F,
L₈₁ and L₈₂ may each independently be a single bond or CRR′,
R and R′ may each independently be hydrogen, deuterium, a halogen, a cyano group, a hydroxy group, a C₁-C₃₀ alkyl group, a C₁-C₃₀ halogenated alkyl group, a C₁-C₃₀ alkoxy group, a C₃-C₃₀ cycloalkyl group, or a C₃-C₃₀ cycloalkoxy group,
n81 and n82 may each independently be 1, 2, or 3,
x81 may be 0 or 1,
R₈₁ to R₈₄ may each independently be a linear, branched, or cyclic C₁-C₃₀ monovalent hydrocarbon group that optionally includes a heteroatom,
an adjacent two groups among R₈₁ to R₈₄ may optionally be linked to each other to form a condensed ring, and
R₈₅ and R₈₆ may each independently be: hydrogen; a halogen; or a linear, branched, or cyclic C₁-C₃₀ monovalent hydrocarbon group that optionally includes a heteroatom.

The quencher may be included in an amount in a range of about 0 parts by weight to about 10 parts by weight, 0.05 parts by weight to about 5 parts by weight, or about 0.1 parts by weight to about 3 parts by weight, based on 100 parts by weight of the polymer. When the amount of the photoacid generator is satisfied within the ranges above, proper resolution may be achieved, and problems related to foreign particles after development or during stripping may be reduced.

One type of the surfactant may be used, or a combination of two or more different types of the surfactant may be used.

### <Base Resin>

The resist composition may further include a base resin that is different from the polymer.

The base resin may include a repeating unit represented by Formula 20 and including an acid labile group:

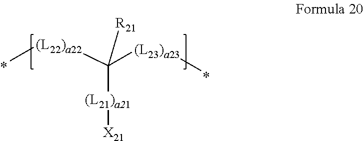

wherein, in Formula 20,
L₂₁ to L₂₃ may each independently be: a single bond; O; S; C(═O); C(═O)O; OC(═O); C(═O)NH; NHC(═O); or a linear, branched, or cyclic C₁-C₃₀ divalent hydrocarbon group that optionally includes a heteroatom,
a21 to a23 may each independently be an integer from 1 to 4,
R₂₁ may be: hydrogen; deuterium; a halogen; a cyano group; a hydroxy group; an amino group; a carboxylic acid group; a thiol group; an ester moiety; a sulfonate ester moiety; a carbonate moiety; a lactone moiety; a sultone moiety; a carboxylic anhydride moiety; or a linear, branched, or cyclic C₁-C₃₀ monovalent hydrocarbon group that optionally includes a heteroatom,
X₂₁ may be an acid labile group, and
* indicates a binding site to a neighboring atom.

The base resin including the repeating unit represented by Formula 20 may be decomposed under the action of an acid to generate a carboxyl group, thereby being converted to have alkali-solubility.

In addition to the repeating unit represented by Formula 20, the base resin may further include a repeating unit represented by Formula 30:

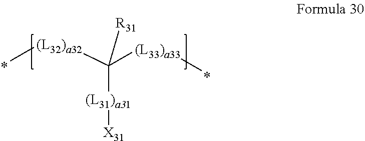

wherein, in Formula 30,
L₃₁ to L₃₃ may each independently be: a single bond; O; S; C(═O); C(═O)O; OC(═O); C(═O)NH; NHC(═O); or a linear, branched, or cyclic C₁-C₃₀ divalent hydrocarbon group that optionally includes a heteroatom,
a31 to a33 may each independently be an integer from 1 to 4,
R₃₁ may be: hydrogen; deuterium; a halogen; a cyano group; a hydroxy group; an amino group; a carboxylic acid group; a thiol group; an ester moiety; a sulfonate ester moiety; a carbonate moiety; a lactone moiety; a sultone moiety; a carboxylic anhydride moiety; or a linear, branched, or cyclic C₁-C₃₀ monovalent hydrocarbon group that optionally includes a heteroatom,
X₃₁ may be a non-acid labile group, and
* indicates a binding site to a neighboring atom.

For example, in ArF lithography processes, X₃₁ may include a lactone ring as a polar moiety, and in KrF, EB, and EUV lithography processes, X₃₁ may be a phenol.

In an embodiment, the base resin may further include a moiety including an anion and/or a cation. For example, the base resin may further include a moiety in which a photoacid generator and/or a quencher are induced to bind to the side chain.

The base resin may have a weight average molecular weight (Mw) in a range of about 1,000 to 500,000, for example, about 3,000 to about 100,000, wherein the weight average molecular weight (Mw) is measured by gel permeation chromatography using a tetrahydrofuran solvent and polystyrene as a standard material.

The base resin may have PDI (Mw/Mn) in a range of about 1.0 to about 3.0, for example, about 1.0 to about 2.0. When the PDI of the polymer is satisfied within the ranges above, there is a less chance of remaining foreign substances on a pattern, or deterioration of a pattern profile may be minimized. Accordingly, the resist composition including the polymer may be more suitable for forming fine patterns.

The base resin may be prepared by any suitable method, for example, a method in which unsaturated bond-containing monomer(s) is dissolved in an organic solvent and then thermally polymerized in the presence of a radical initiator.

In the base resin, a mole fraction (mol %) of each repeating unit derived from each monomer is as follows, but is not limited thereto:
i) the repeating unit represented by Formula 20 is included in an amount in a range of about 1 mol % to about 60 mol %, for example, about 5 mol % to about 50 mol %, and for example, about 10 mol % to about 50 mol %; and
ii) the repeating unit represented by Formula 30 is included in an amount in a range of about 40 mol % to about 99 mol %, for example, about 50 mol % to about 95 mol %, and for example, about 50 mol % to about 90 mol %.

The base resin may be a homopolymer, or may include a mixture of two or more types of polymers having a different composition, a different weight average molecular weight, and/or a different PDI.

### <Optional Components>

The resist composition may further include a surfactant, a cross-linking agent, a leveling agent, a colorant, or any combination thereof, as needed.

The resist composition may further include a surfactant to improve a coating property and developability. Examples of the surfactant may include: a non-ionic surfactant, such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate, polyethylene glycol distearate, and the like; and the like. For use as the surfactant, a commercially available product may be used, or a synthetic product may be used. Examples of the commercially available product may include KP341 (manufactured by Shin-Etsu Chemical Co., Ltd.), POLYFLOW No. 75 and POLYFLOW No. 95 (manufactured by Kyoeisha Chemical Co., Ltd.), FTOP EF301, FTOP EF303, and FTOP EF352 (manufactured by Mitsubishi Materials Electronic Chemicals Co., Ltd.), MEGAFACE F171 (registered trademark), MEGAFACE F173, R40, R41, and R43 (manufactured by DIC Corporation), Fluorad FC430 (registered trademark) and Fluorad FC431 (manufactured by 3M Company), AsahiGuard AG710 (product of AGC Corporation), Surflon S-382 (registered trademark), Surflon SC-101, Surflon SC-102, Surflon SC-103, Surflon SC-104, Surflon SC-105, and Surflon SC-106 (manufactured by AGC Seimi Chemical Co., Ltd.), and the like.

The surfactant may be included in an amount in a range of about 0 parts by weight to about 20 parts by weight, based on 100 parts by weight of the polymer.

One type of the surfactant may be used, or a combination of two or more different types of the surfactant may be used.

A method of preparing the resist composition is not particularly limited, and for example, a method of mixing a polymer, a photoacid generator, and optional components added as necessary in an organic solvent may be used. The temperature or time at the mixing is not particularly limited. Filtration may be performed after the mixing as needed.

### [Pattern Formation Method]

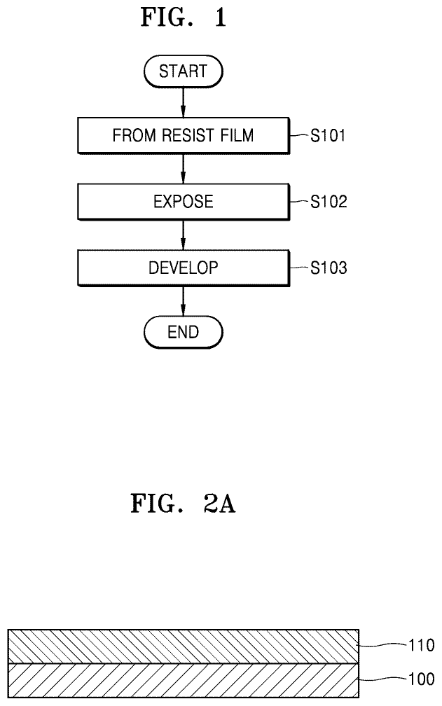

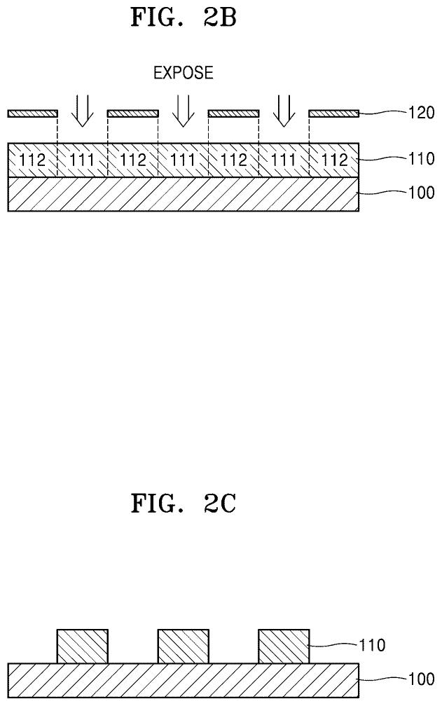

Hereinafter, a pattern formation method according to embodiments will be described in more detail with reference to FIGS. 1 and 2. FIG. 1 is a flowchart representing a pattern formation method according to an embodiment, and FIGS. 2A to 2C are each a side cross-sectional view illustrating a pattern formation method according to an embodiment. Hereinafter, an example of a pattern formation method using a negative-tone resist composition will be described, but embodiments of the disclosure are not limited thereto.

Referring to FIG. 1, the pattern formation method may include: forming a resist film by applying a resist composition (S101); exposing at least a portion of the resist film with high-energy rays (S102); and developing the resist film exposed by using a developing solution (S103). The operations above may be omitted as necessary, or may be performed in different orders.

First, a board 100 is prepared. The board 100 may be, for example, a semiconductor board, such as a silicon board or a germanium board, or may be formed of glass, quartz, ceramic, copper, and the like. In an embodiment, the board 100 may include a Group III-V compound, such as GaP, GaAs, GaSb, and the like.

A resist film 110 may be formed by applying a resist composition to a desired thickness onto the board 100 by a coating method. As needed, the method may include heating (pre-baking (PB) or post-annealing baking (PAB) operations) to remove the organic solvent remaining in the resist film 110.

The coating method may include spin coating, dipping, roller coating, or other common coating methods. In an embodiment, spin coating may be used, and the thickness of the resist film 110 may be adjusted by controlling the viscosity, concentration, and/or spin speed of the resist composition. In an embodiment, the thickness of the resist film 110 may be in a range of about 10 nm to about 300 nm. In one or more embodiments, a thickness of the resist film 110 may be in a range of about 30 nm to about 200 nm.

The lower limit of a PB temperature may be 60° C. or higher, for example, 80° C. or higher. In addition, the upper limit of a PB temperature may be 150° C. or lower, for example, 140° C. or lower. The lower limit of a PB time may be 5 seconds or more, for example, 10 seconds or more. The upper limit of a PB time may be 600 seconds or less, for example, 300 seconds or less.

Before coating the resist composition on the board 100, an etch target film (not shown) may be further formed on the board 100. The etch target film may refer to a layer on which an image is transferred from a resist pattern and converted into a certain pattern. In an embodiment, the film to be etched may be formed to include, for example, an insulating material, such as silicon oxide, silicon nitride, or silicon oxynitride. In one or more embodiments, the film to be etched may be formed to include a conductive material, such as metal, metal nitride, metal silicide, or metal silicide nitride. In one or more embodiments, the film to be etched may be formed to include a semiconductor material, such as polysilicon.

In an embodiment, an anti-reflection film may be further formed on the board 100 to maximize the efficiency of the resist. The anti-reflection film may be an organic-based anti-reflection layer or an inorganic-based anti-reflection layer.

In an embodiment, a protective film may be further provided on the resist film 110 in order to reduce the influence of alkaline impurities included in the process. Further, in the case of immersion exposure, for example, a protective film for immersion may be provided on the resist film 110 to avoid direct contact between the immersion medium and the resist film 110.

Next, at least a portion of the resist film 110 may be exposed to high-energy rays. For example, high-energy rays passing through a mask 120 may be irradiated to at least a portion of the resist film 110. As such, the resist film 110 may have an exposed portion 111 and a non-exposed portion 112.

In the exposing, the polymer may be ionized to generate radical cations and electrons.

The exposure may be carried out by irradiating high-energy ray through a mask having a predetermined pattern and by using liquid, such as water or the like, as a medium in some cases. Examples of the high-energy rays may include: electromagnetic waves, such as ultraviolet ray, far-ultraviolet rays, extreme ultraviolet rays (EUV rays, wavelength of 13.5 nm), X-rays, γ-rays, and the like; charged particle beams, such as electron beams (EBs), a rays, and the like; and the like. The irradiation of such high-energy rays may be collectively referred to as “exposure”.

For use as a light source of the exposure, various types of irradiation including irradiating laser beams in the ultraviolet region, such as KrF excimer laser (wavelength of 248 nm), ArF excimer laser (wavelength of 193 nm), and F2 excimer laser (wavelength of 157 nm), irradiating harmonic laser beams in the far ultraviolet or vacuum ultraviolet region by a wavelength conversion method using laser beams from a solid-state laser source (e.g., YAG or semiconductor laser), irradiating electron beams or EUV rays, or the like may be used. Upon the exposure, the exposure may be performed through a mask corresponding to a desired pattern. However, when the light source of the exposure is EBs, the exposure may be performed by direct drawing without using a mask.

The integral dose of the high-energy rays may be 2,000 mJ/cm² or less, for example, 500 mJ/cm² or less, in the case of using EUV rays as the high-energy rays. In addition, in the case of using EBs as the high-energy rays, the integral dose of the high-energy rays may be 5,000 μC/cm² or less, for example, 1,000 μC/cm² or less.

In addition, post-exposure baking (PEB) may be performed after the exposure. The lower limit of a PEB temperature may be 50° C. or higher, for example, 80° C. or higher. The upper limit of the PEB temperature may be 180° C. or less, for example, 130° C. or less. The lower limit of a PEB time may be 5 seconds or more, for example, 10 seconds or more. The upper limit of the PEB time may be 600 seconds or less, for example, 300 seconds or less.

Next, the exposed resist film 110 may be developed by using a developing solution. The exposed portion 111 may remain without being washed away by the developing solution, whereas the non-exposed portion 112 may be washed away by the developing solution.

For use as the developing solution, an alkali developing solution, a developing solution containing an organic solvent (hereinafter also referred to as “organic developing solution”), and the like may be used. As a developing method, a dipping method, a puddle method, a spray method, a dynamic administration method, and the like may be used. The developing temperature may be, for example, 5° C. or more and 60° C. or less, and the developing time may be, for example, 5 seconds or more and 300 seconds or less.

The alkali developing solution may be, for example, an alkaline aqueous solution which dissolves at least one alkaline compound, such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, ethyldimethylamine, triethanolamine, tetramethyl ammonium hydroxide (TMAH), pyrrole, piperidine, choline, 1,8-diazabicyclo[5.4.0]-7-undecene (DBU), 1,5-diazabicyclo[4.3.0]-5-nonene, and the like. The alkaline developing solution may further include a surfactant.

The lower limit of the amount of the alkaline compound in the alkaline developing solution may be 0.1 mass % or more, for example, 0.5 mass % or more, and for example, 1 mass % or more. In addition, the upper limit of the amount of the alkaline compound in the alkaline developing solution may be 20 mass % or less, for example, 10 mass % or less, and for example, 5 mass % or less.

After the development, a resulting resist pattern may be washed with ultrapure water, and subsequently, the water remaining on the board 100 and the pattern may be removed.

As an organic solvent contained in the organic developing solution, for example, the same organic solvent as the organic solvent described in the <Organic solvent> of the [Resist composition] may be used.

The lower limit of the amount of the organic solvent in the organic developing solution may be 80 mass % or more, for example, 90 mass % or more, and for example, 95 mass % or more, and for example, 99 mass % or more.

The organic developing solution may also include a surfactant. In addition, the organic developing solution may include a trace amount of moisture. In addition, upon the development, the solvent may be substituted with a solvent of a different kind from the organic developing solution to stop the development.

The resist pattern after development may be further cleaned by using a washing solution. For use as the washing solution, ultrapure water, rinsing liquid, and the like may be used. The rinsing liquid is not particularly limited as long as it does not dissolve the resist pattern, and a solution containing a general organic solvent may be used. For example, the rinsing liquid may be an alcohol-based solvent or an ester-based solvent. After the washing, the rinsing liquid remaining on the board and the pattern may be removed. In addition, when ultrapure water is used, the water remaining on the board and the pattern may be removed.

In addition, the developing solution may be used either individually or in a combination of two or more types.

After the resist pattern is formed as described above, a patterned interconnection board may be obtained. An etching method may be performed by known methods including: dry etching using plasma gas; wet etching using an alkali solution, a cupric chloride solution, a ferric chloride solution; and the like.

After forming the resist pattern, plating may be performed. Although not particularly limited, a plating method may include, for example, copper plating, solder plating, nickel plating, gold plating, and the like.

The resist pattern remaining after etching may be peeled with an organic solvent. Although not particularly limited, examples of the organic solvent may include propylene glycol monomethyl ether acetate (PGMEA) propylene glycol monomethyl ether (PGME), ethyl lactate (EL), and the like. Although not particularly limited, examples of the exfoliation method may include an immersion method, a spray method, and the like. In addition, the interconnection board on which the resist pattern is formed may be a multi-layer interconnection board or may have small-diameter through-holes.

In an embodiment, the interconnection board may be formed by a lift-off method in which a resist pattern is formed and then metal is deposited in a vacuum and then the resist pattern is dissolved by using a solution.

The disclosure will be described in more detail with reference to Examples and Comparative Examples below, but the technical scope of the disclosure is not limited only thereto.

### EXAMPLES

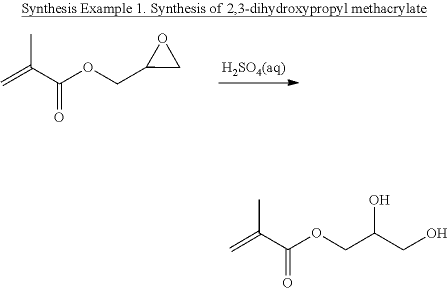

A solution in which 14.49 g of glycidyl methacrylate was mixed with 25 ml of THF was placed in an ice bath to cool, and 125 mL of a 2 M H₂SO₄ aqueous solution was added dropwise thereto. The resulting solution was stirred at room temperature for 7 hours.

The THF solvent was removed by using an evaporator, and an extraction process using 100 mL of dichloromethane (DCM) was repeated 5 times to obtain 500 mL of an organic layer solution. The residual moisture in the organic layer was removed by using Na₂SO₄, and the resulting organic layer was filtered through a filter paper to obtain a filtrate, and the filtrate was placed in an evaporator to remove the solvent.

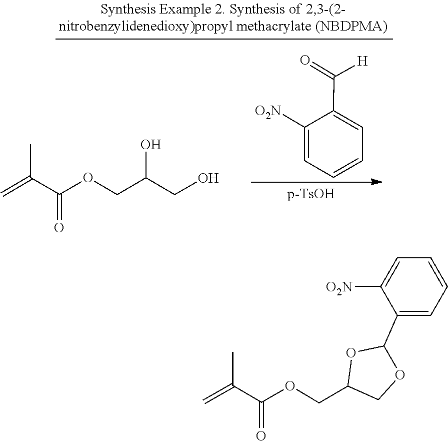 [SMILES: C=C(C)C(=O)OCC(O)CO ; O=Cc1ccccc1[N+](=O)[O-] ; C=C(C)C(=O)OCC1COC(c2ccccc2[N+](=O)[O-])O1]

P-toluenesulfonic acid, 150 mL of cyclohexane, ortho-nitrobenzaldehyde, 2,3-dihydroxypropyl, and methacrylate were added in the stated order to a 250 mL round bottom flask, and the mixture was stirred under reflux by using a dean-stark apparatus at 100° C. in an oil bath for 15 hours.

After 15 hours, the solvent was removed by using an evaporator, and the reaction mixture was dissolved in 120 mL of ethyl acetate. Then, an extraction process was performed by using 60 mL of a saturated NaHCO₃ aqueous solution three times, 60 mL of distilled water once, and 60 mL of brine.

Afterwards, the residual moisture in the organic layer was removed by using Na₂SO₄, and the resulting organic layer was filtered through a filter paper to obtain a filtrate. The filtrate thus obtained was concentrated, and then subjected to column chromatography using an ethylene acetate (EA)/hexane solution (at a volume ratio of 2:8) to obtain a product.

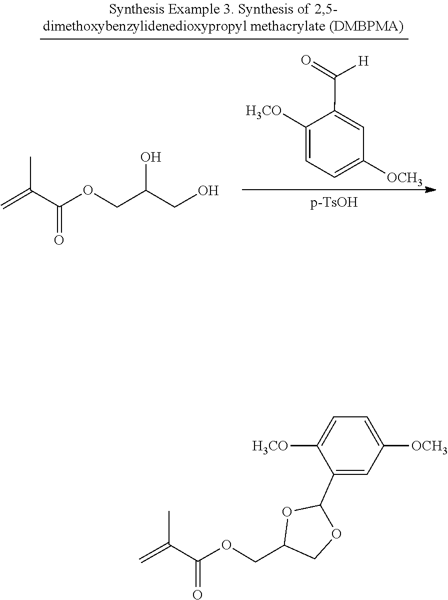 [SMILES: C=C(C)C(=O)OCC(O)CO ; COc1ccc(OC)c(C=O)c1 ; C=C(C)C(=O)OCC1COC(c2cc(OC)ccc2OC)O1]

P-toluenesulfonic acid, 80 mL of cyclohexane, 2.5-dimethoxy benzaldehyde, and 2,3-dihydroxypropyl methacrylate were added in the stated order to a 250 ml round bottom flask. The mixture was stirred under reflux by using a dean-stark apparatus at 100° C. in an oil bath for 15 hours.

After 15 hours, the solvent was removed by using an evaporator, and the reaction mixture was dissolved in 120 mL of ethyl acetate. Then, an extraction process was performed by using 60 mL of a saturated NaHCO₃ aqueous solution three times, 60 mL of distilled water once, and 60 mL of brine.

Afterwards, the residual moisture in the organic layer was removed by using Na₂SO₄, and the resulting organic layer was filtered through a filter paper to obtain a filtrate. The filtrate thus obtained was concentrated, and then subjected to column chromatography using an ethylene acetate (EA)/hexane solution (at a volume ratio of 2:8) to obtain a product.

### Example 1. Synthesis of Polymer 1

### 1. Synthesis of Polymer 1-1

Acetoxy styrene, 2-ethyl-2-adamantyl methacrylate (EAMA), NBDPMA, 2-oxohexahydro-2H-3,5-methanocyclopenta[b]furan-6-yl methacrylate (OMF), V601 (CAS: 2589-57-3), and propylene glycol methyl ether (PGME) were added into a 20 mL vial and stirred in an oil bath at 85° C. for 3 hours. After 3 hours, the reaction solution was diluted with a small amount of THF and allowed for precipitation in methanol. While solids thus obtained were collected by vacuum filtration and dried in a vacuum oven at 30° C.

### 2. Synthesis of Polymer 1-2

The resulting polymer was mixed with 28% aqueous solution of ammonium hydroxide (70 molar equivalent of acetyl group in copolymer) and methanol (1 mL per 0.1 g of copolymer), and the mixed solution was stirred overnight at room temperature. Afterwards, the solvent was removed by using an evaporator, and the resulting solution was diluted with THF. The TFT was removed again by using an evaporator, and this process was repeated until the reaction solution became transparent.

Afterwards, the copolymer thus obtained was dissolved in ethyl acetate, and an extraction process using distilled water was performed thereon three times to obtain an organic layer. The residual moisture was removed therefrom by using Na₂SO₄, and the resulting organic layer was filtered through a filter paper to obtain only a filtrate. Ethyl acetate was then removed from the filtrate by using an evaporator.

### 3. Synthesis of Polymer 1

The sample thus prepared was mixed with THF (20 mL per 0.10 g of copolymer) and an aqueous solution of citric acid (9.60 g of citric acid+500 mL of distilled water). The mixed solution was stirred overnight at room temperature. Afterwards, an extraction process using ethyl acetate and distilled water was performed on the reaction solution three times to obtain an organic layer, and the residual moisture was removed therefrom by using Na₂SO₄. The resulting organic layer was filtered through a filter paper to obtain only a filtrate, and ethyl acetate was removed therefrom by using an evaporator. The sample thus prepared was diluted with THF and was allowed for precipitation in distilled water. White solids thus obtained were collected by vacuum filtration and dried in a vacuum oven at 80° C., so as to obtain Polymer 1 including a repeating unit represented by Formula P1, a repeating unit represented by Formula P2, a repeating unit represented by Formula P3, and a repeating unit represented by Formula P4:

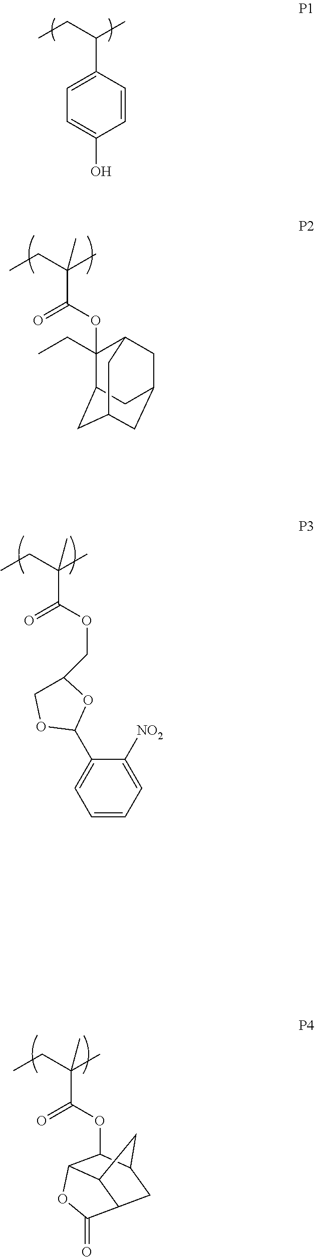

### Example 2. Synthesis of Polymer 2

### 1. Synthesis of Polymer 2-1

Acetoxy styrene, EAMA, DMBPMA, OMF, V601, and PGME added into a 20 mL vial and stirred in an oil bath at 85° C. for 3 hours. After 3 hours, the reaction solution was diluted with a small amount of THF and allowed for precipitation in methanol. While solids thus obtained were collected by vacuum filtration and dried in a vacuum oven at 30° C.

### 2. Synthesis of Polymer 2-2

The resulting polymer was mixed with 28% aqueous solution of ammonium hydroxide (70 molar equivalent of acetyl group in copolymer) and methanol (1 mL per 0.1 g of copolymer), and the mixed solution was stirred overnight at room temperature. Afterwards, the solvent was removed by using an evaporator, and the resulting solution was diluted with THF. The TFT was removed again by using an evaporator, and this process was repeated until the reaction solution became transparent.

Afterwards, the copolymer thus obtained was dissolved in ethyl acetate, and an extraction process using distilled water was performed thereon three times to obtain an organic layer. The residual moisture was removed therefrom by using Na₂SO₄, and the resulting organic layer was filtered through a filter paper to obtain only a filtrate. Ethyl acetate was then removed from the filtrate by using an evaporator.

### 3. Synthesis of Polymer 2

The sample thus prepared was mixed with THF (20 mL per 0.10 g of copolymer) and an aqueous solution of citric acid (9.60 g of citric acid+500 mL of distilled water). The mixed solution was stirred overnight at room temperature. Afterwards, an extraction process using ethyl acetate and distilled water was performed on the reaction solution three times to obtain an organic layer, and the residual moisture was removed therefrom by using Na₂SO₄. The resulting organic layer was filtered through a filter paper to obtain only a filtrate, and ethyl acetate was removed therefrom by using an evaporator. Afterwards, the sample thus prepared was diluted with THF and was allowed for precipitation in distilled water. White solids thus obtained were collected by vacuum filtration and dried in a vacuum oven at 80° C., so as to obtain Polymer 2 including a repeating unit represented by Formula P1, a repeating unit represented by Formula P2, a repeating unit represented by Formula P4, and a repeating unit represented by Formula P5:

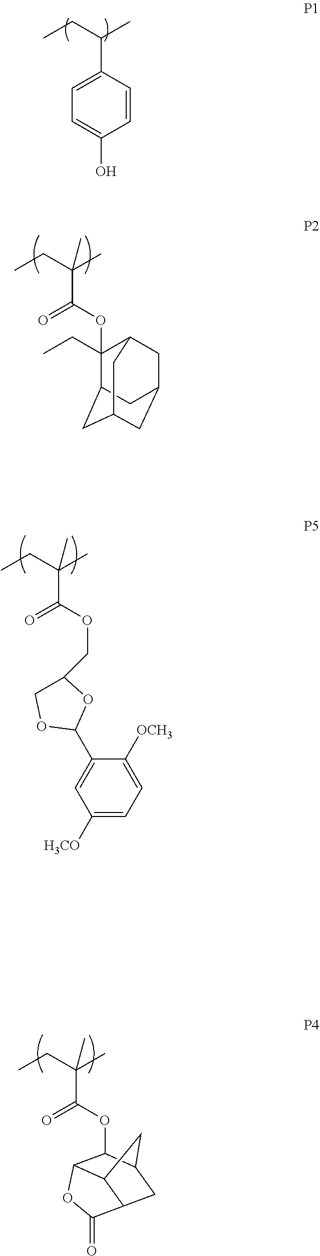

### Comparative Examples 1 and 2. Synthesis of Comparison Polymers 1 and 2

Comparison Polymers 1 and 2, each including a repeating unit represented by Formula P1, a repeating unit represented by Formula P2, and a repeating unit represented by Formula P4, were synthesized in the same manner as in Example 1, except that NBDPMA was not used and each monomer was used at different ratios:

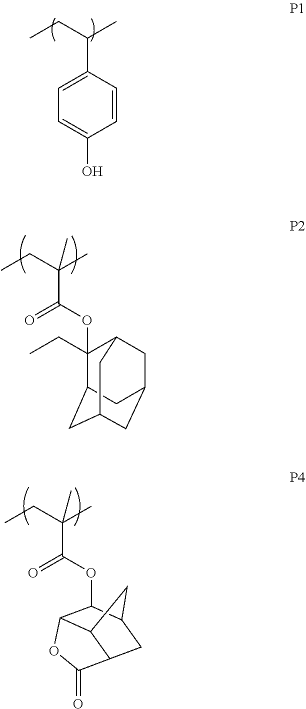

### Comparative Example 3. Synthesis of Comparison Polymer 3

Comparison Polymer 3 including a repeating unit represented by Formula P1, a repeating unit represented by Formula P2, a repeating unit represented by Formula CP1, and a repeating unit represented by Formula P4 was synthesized in the same manner as in Example 1, except that (2-(naphthalene-2-yl)-1,3-dioxolan-4-yl)methyl methacraylate) (NDMA) was used instead of NBDPMA:

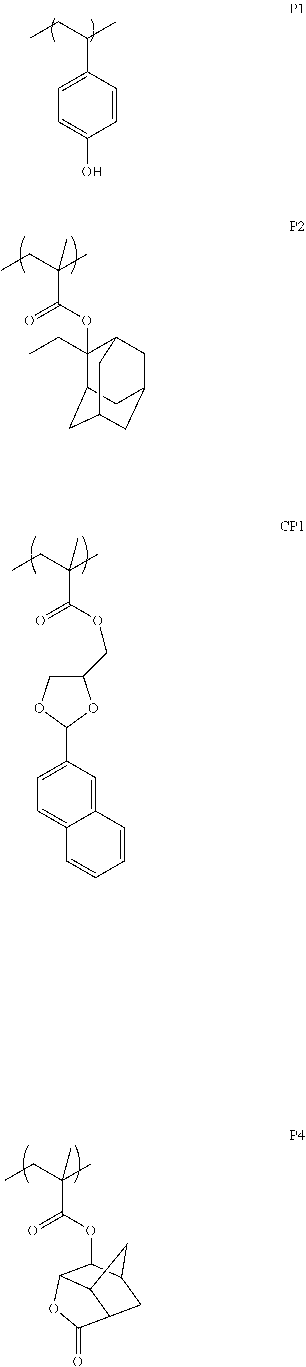

### Comparative Example 4. Synthesis of Comparison Polymer 4

Comparison Polymer 4 including a repeating unit represented by Formula P1, a repeating unit represented by Formula P2, a repeating unit represented by Formula CP2, and a repeating unit represented by Formula P4 was synthesized in the same manner as in Example 1, except that (2-(4-hydroxyphenyl)-2-methyl-1,3-dioxolan-4-yl)methyl methacrylate) (MPHMA) was used instead of NBDPMA:

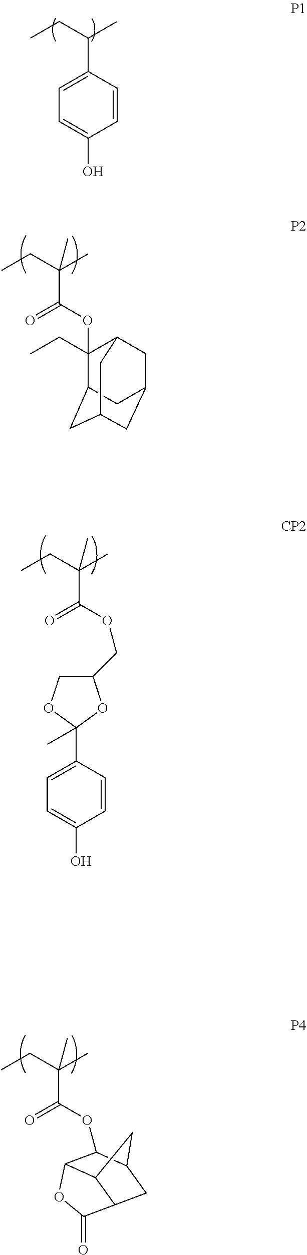

### Comparative Example 5. Synthesis of Comparison Polymer 5

Comparison Polymer 5 including a repeating unit represented by Formula P1, a repeating unit represented by Formula P2, a repeating unit represented by Formula CP3, and a repeating unit represented by Formula P4 was synthesized in the same manner as in Example 1, except that (2-phenyl-1,3-dioxolan-4-yl)methyl methacrylate) (PMA) was used instead of NBDPMA:

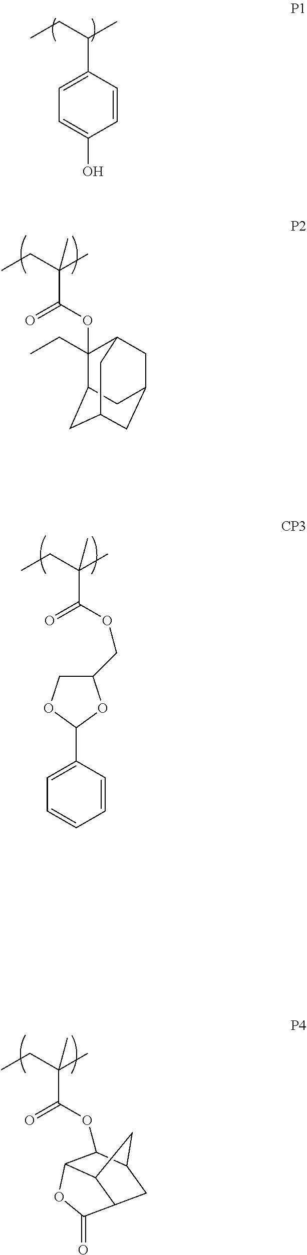

In Table 1 below, the molecular weight, PDI, and yield of Polymers 1 and 2 and Comparison Polymers 1 to 5 are shown, and in Table 2 below, the raw material ratios for Polymers 1 and 2 and Comparison Polymers 1 to 5 are shown. The molecular weight shown in Table 1 was measured by using gel permeation chromatography with polystyrene standard and THF solvent. The raw material ratio shown in Table 2 was analyzed by using H-NMR.

TABLE 1

| | Mₙ^{GPC} | M_{W}^{GPC} | | Copolymer yield |
|---|---|---|---|---|
| | (g/mol) | (g/mol) | PDI | (%) |
| Polymer 1 | 6,800 | 14,800 | 2.16 | 66.1 |
| | | | | (1 g scale) |
| Polymer 2 | 5,700 | 10,100 | 1.79 | 24.7 |
| | | | | (0.5 g scale) |
| Comparison | 6,313 | 11,549 | 1.83 | 80.2 |
| Polymer 1 | | | | (1 g scale) |
| Comparison | 6,842 | 11,605 | 1.70 | 81.6 |
| Polymer 2 | | | | (1 g scale) |
| Comparison | 6,734 | 12,045 | 1.78 | 76.5 |
| Polymer 3 | | | | (1 g scale) |
| Comparison | 7,105 | 11,489 | 1.62 | 61.2 |
| Polymer 4 | | | | (1 g scale) |
| Comparison | 6,869 | 12,445 | 1.81 | 84.2 |
| Polymer 5 | | | | (1 g scale) |

TABLE 2

| | Acetoxy | | Raw material in | |
|---|---|---|---|---|
| | styrene | EAMA | use/ratio | OMF |
| Polymer 1 | 5 | 2 | NBDPMA/1 | 2 |
| Polymer 2 | 5 | 2 | DMBPMA/1 | 2 |
| Comparison | 6 | 2 | 0 | 2 |
| Polymer 1 | | | | |
| Comparison | 5 | 3 | 0 | 2 |
| Polymer 2 | | | | |
| Comparison | 5 | 2 | NDMA/1 | 2 |
| Polymer 3 | | | | |
| Comparison | 5 | 2 | MPHMA/1 | 2 |
| Polymer 4 | | | | |
| Comparison | 5 | 2 | PMA/1 | 2 |
| Polymer 5 | | | | |

### Evaluation Example 1

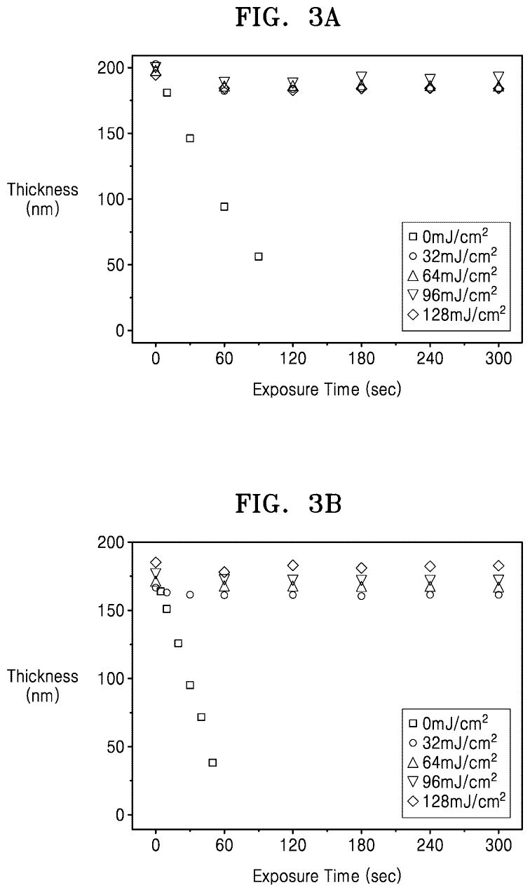

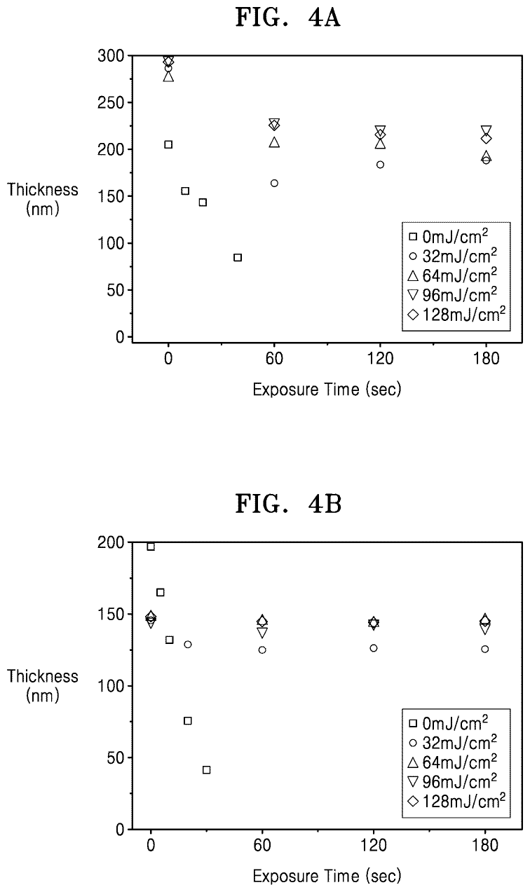

According to evaluation methods described in Table 3, dissolution rates and residual thickness ratios after development for Polymers 1 and 2 and Comparison Polymers 1 to 5 were measured, and the results are shown in Tables 4 and 5 and FIGS. 3A, 3B, 4A, and 4B. In Table 4, DR^{PAB} represents a dissolution rate after PAB, and DR^{PEB} represents a dissolution rate after PEB.

### Table 3

1. A solution prepared by adding 4.5 g of PGMEA solvent and 25 g of PAG to 0.5 g of polymer was spin-coated (5,000 rpm, 50 sec) on a silicon wafer after removing foreign substances by using a 0.1 um syringe filter.

2. The spin-coated wafer was dried on a hot plate at 110° C. for 1.5 minutes (referred to as PAB).

3. Exposure was performed at 32 mJ/cm² by using an I-line exposure device (365 nm), and post-exposure bake (PEB) was performed at 90° C. for 1 minute.

4. Samples on which PAB or PEB was completed was immersed in nBA for 1 minutes to measure changes in the thickness, and the measured value was divided by time to measure the dissolution rate.

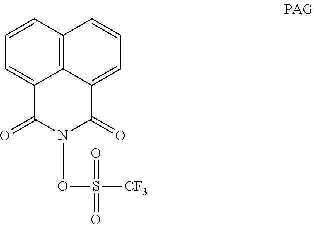 [SMILES: O=C1c2cccc3cccc(c23)C(=O)N1OS(=O)(=O)C(F)(F)F]

TABLE 4

| | DR^{PAB} (nm/sec) | DR^{PEB} (nm/sec) |
|---|---|---|
| Polymer 1 | 3.20 | ≈0 |
| Polymer 2 | 2.85 | ≈0 |
| Comparison Polymer 1 | 2.98 | 2.04 |
| Comparison Polymer 2 | 5.20 | 0.84 |
| Comparison Polymer 3 | 6.12 | 1.02 |
| Comparison Polymer 4 | 3.63 | 0.98 |
| Comparison Polymer 5 | 1.24 | 0.78 |

Referring to Table 4, it can be expected that Polymers 1 and 2 will have excellent performance as photoresists due to low dissolution rates after PEB.

TABLE 5

| | Residual thickness ratio |
|---|---|
| | after development |
| | (%) |
| Polymer 1 | 90.5 |
| Polymer 2 | 96.6 |
| Comparison Polymer 1 | 57.1 |
| Comparison Polymer 2 | 85.8 |
| Comparison Polymer 3 | 63.2 |
| Comparison Polymer 4 | 74.6 |
| Comparison Polymer 5 | 84.6 |

(In Table 5, the residual thickness ratio after development indicates the ratio of remaining film thickness after irradiating light of 32 mJ/cm² and undergoing heat treatment (PEC) and development for 60 seconds.)

FIGS. 3A and 3B are each a diagram showing the results of measuring the thickness of each of Polymers 1 and 2 according to the exposure time, and FIGS. 4A and 4B are each a diagram showing the results of measuring the thickness of each of Comparison Polymers 1 and 2 according to the exposure time.

Referring to Table 5 and FIGS. 3A, 3B, 4A, and 4B, it was confirmed that Polymers 1 and 2 showed a small decrease in thickness after exposure and high uniformity compared to Comparison Polymers 1 and 2.

According to the one or more embodiments, embodiments of the disclosure may provide a resist composition capable of providing improved sensitivity and/or improved resolution.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A resist composition comprising:
a polymer including a first repeating unit represented by Formula 1;
a photoacid generator; and
an organic solvent, 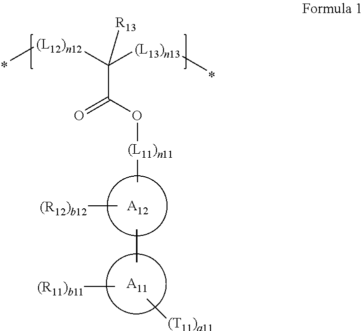
wherein, in Formula 1,
L₁₁ to L₁₃ are each independently: a single bond; O; S; C(═O); C(═O)O; OC(═O); C(═O)NH; NHC(═O); or a linear, branched, or cyclic C₁-C₃₀ divalent hydrocarbon group that optionally includes a heteroatom,
n11 to n13 are each independently an integer from 1 to 4,
A₁₁ is a C₆-C₃₀ aryl group or a C₁-C₃₀ heteroaryl group,
A₁₂ is a C₁-C₃₀ divalent hydrocarbon group including at least two oxygens (O),
T₁₁ is a nitro group or a C₁-C₂₀ alkoxy group,
a11 is an integer from 1 to 5,
R₁₁ to R₁₃ are each independently: hydrogen; deuterium; a halogen; a cyano group; a hydroxy group; an amino group; a carboxylic acid group; a thiol group; an ester moiety; a sulfonate ester moiety; a carbonate moiety; a lactone moiety; a sultone moiety; a carboxylic anhydride moiety; or a linear, branched, or cyclic C₁-C₃₀ monovalent hydrocarbon group that optionally includes a heteroatom,
b11 and b12 are each independently an integer from 1 to 10, and
* indicates a binding site to a neighboring atom.

2. The resist composition of claim 1, wherein L₁₁ to L₁₃ are each independently:
a single bond; O; S; C(═O); C(═O)O; OC(═O); C(═O)NH; NHC(═O); a substituted or unsubstituted C₁-C₃₀ alkylene group; a substituted or unsubstituted C₃-C₃₀ cycloalkylene group; a substituted or unsubstituted C₃-C₃₀ heterocycloalkylene group; a substituted or unsubstituted C₂-C₃₀ alkenylene group; a substituted or unsubstituted C₃-C₃₀ cycloalkenylene group; a substituted or unsubstituted C₃-C₃₀ heterocycloalkenylene group; a substituted or unsubstituted C₆-C₃₀ arylene group; or a substituted or unsubstituted C₁-C₃₀ heteroarylene group.

3. The resist composition of claim 1, wherein A₁₁ is a benzene group, a naphthalene group, a phenanthrene group, an anthracene group, a pyrene group, a chrysene group, or an indene group.

4. The resist composition of claim 1, wherein A₁₂ has an acetal structure within a ring.

5. The resist composition of claim 1, wherein a moiety represented by 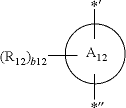
in Formula 1 is a group represented by Formula 1B: 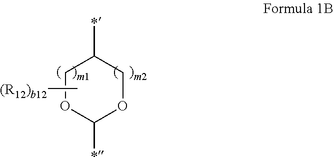
wherein, in Formula 1B,
m1 and m2 are each independently an integer from 0 to 5,
** indicates a binding site to L₁₁ in Formula 1,
** indicates a binding site to A₁₁ in Formula 1, and
R₁₂ and b12 are each as defined in Formula 1.

6. The resist composition of claim 1, wherein a moiety represented by 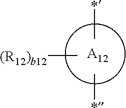
in Formula 1 is a group represented by one of Formulae 1B-1 to 1B-3: 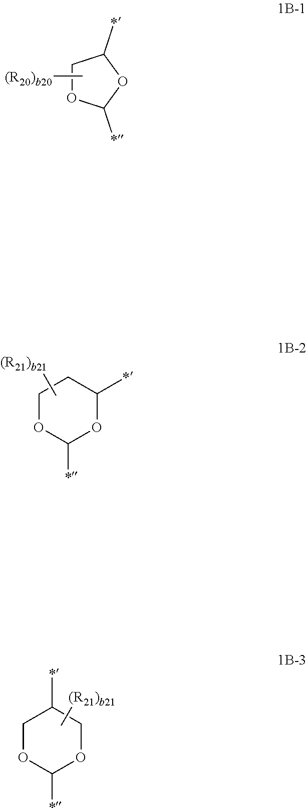
wherein, in Formulae 1B-1 to 1B-3,
R₂₀ and R₂₁ are each independently as defined for R₁₂ in Formula 1,
b20 is an integer from 1 to 4,
b21 is an integer from 1 to 6,
*′ indicates a binding site to L₁₁ in Formula 1, and
*″ indicates a binding site to A₁₁ in Formula 1.

7. The resist composition of claim 1, wherein Ri to R₁₃ are each independently:
hydrogen; deuterium; a halogen; a cyano group; a hydroxy group; an amino group; a carboxylic acid group; a thiol group; or
a C₁-C₂₀ alkyl group, a C₃-C₂₀ cycloalkyl group, or a C₆-C₂₀ aryl group, each unsubstituted or substituted with deuterium, a halogen, a cyano group, a hydroxy group, an amino group, a carboxylic acid group, a thiol group, an ester moiety, a sulfonate ester moiety, a carbonate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₅-C₂₀ cycloalkyl group, a C₃-C₂₀ cycloalkoxy group, a C₆-C₂₀ aryl group, or any combination thereof.

8. The resist composition of claim 1, wherein the first repeating unit is represented by Formula 1-1: 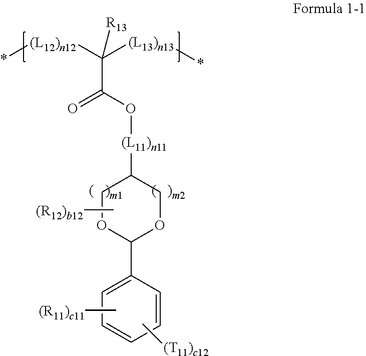
wherein, in Formula 1-1,
m1 and m2 are each independently an integer from 0 to 5,
L₁₁ to Lis, n11 to n13, T₁₁, R₁₁ to R₁₃, and b12 are each as defined in Formula 1,
c11 and c12 are each independently an integer from 1 to 4, and
* indicates a binding site to a neighboring atom.

9. The resist composition of claim 1, wherein the first repeating unit is selected from Group I:

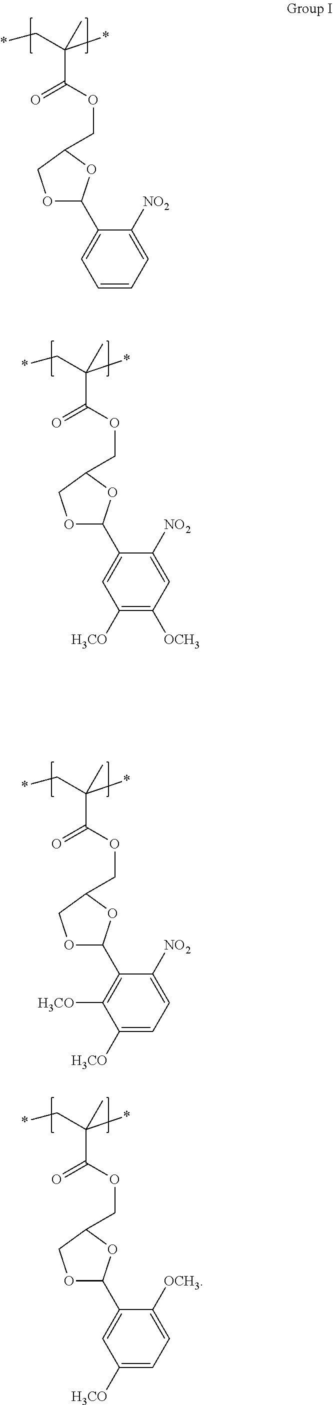

10. The resist composition of claim 1, wherein
the polymer further comprises at least one of a second repeating unit represented by Formula 2 and a third repeating unit represented by Formula 3, 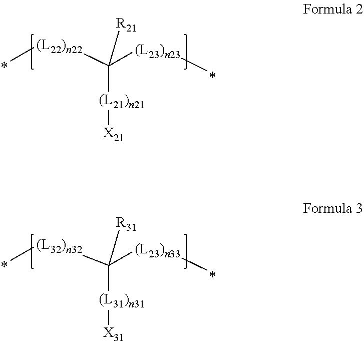
wherein, in Formulae 2 and 3,
L₂₁ to L₂₃ and L₃₁ to L₃₃ are each independently: a single bond; O; S; C(═O); C(═O)O; OC(═O); C(═O)NH; NHC(═O); or a linear, branched, or cyclic C₁-C₃₀ divalent hydrocarbon group that optionally includes a heteroatom,
n21 to n23 and n31 to n33 are each independently an integer from 1 to 4,
R₂₁ and R₃₁ are each independently: hydrogen; deuterium; a halogen; a cyano group; a hydroxy group; an amino group; a carboxylic acid group; a thiol group; an ester moiety; a sulfonate ester moiety; a carbonate moiety; a lactone moiety; a sultone moiety; a carboxylic anhydride moiety; or a linear, branched, or cyclic C₁-C₃₀ monovalent hydrocarbon group that optionally includes a heteroatom,
X₂₁ is a non-acid labile group,
X₃₁ is an acid labile group, and
* indicates a binding site to a neighboring atom.

11. The resist composition of claim 10, wherein the polymer further comprises the second repeating unit and the second repeating unit is represented by Formula 2-1: 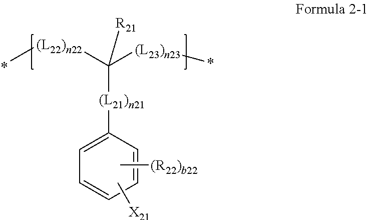
wherein, in Formula 2-1,
L₂₁ to L₂₃, n21 to n23, R₂₁, and X₂₁ are each as defined in Formula 2,
R₂₂ is: hydrogen; deuterium; a halogen; a cyano group; a hydroxy group; a C₁-C₂₀ alkoxy group; or a linear, branched, or cyclic C₁-C₂₀ monovalent hydrocarbon group that optionally includes a heteroatom,
b22 is an integer from 1 to 4, and
* indicates a binding site to a neighboring atom.

12. The resist composition of claim 10, wherein the polymer further comprises the third repeating unit and the third repeating unit is represented by Formula 3-1: 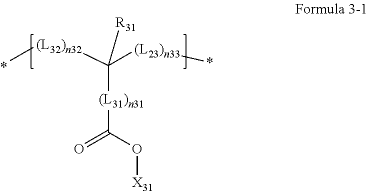
wherein, in Formula 3-1,
L₃₁ to L₃₃, n31 to n33, and R₃₁ are each as defined in Formula 3, and
* indicates a binding site to a neighboring atom.

13. The resist composition of claim 10, wherein
the polymer comprises the third repeating unit represented by Formula 3,
the polymer further comprises a fourth repeating unit represented by Formula 3, and
the third repeating unit and the fourth repeating unit are different from each other.

14. The resist composition of claim 1, wherein an amount of the polymer is in a range of about 0.1 parts by weight to about 80 parts by weight, based on 100 parts by weight of the resist composition.

15. The resist composition of claim 1, wherein the photoacid generator is represented by Formula 7:
B₇₁_{⁺} A₇₁⁻ Formula 7
wherein, in Formula 7,
B₇₁_{⁺} is represented by Formula 7A, A₇₁_{^{−}} is represented by one of Formulae 7B to 7D, and
B₇₁_{⁺} and A₇₁_{^{−}} are optionally linked to each other via a carbon-carbon covalent bond; 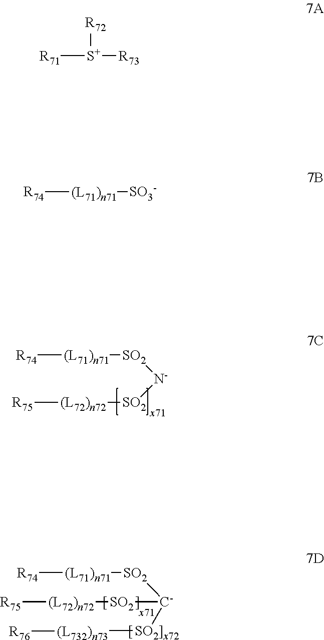
wherein, in Formulae 7A to 7D,
L₇₁ to L₇₃ are each independently a single bond or CRR′,
R and R′ are each independently hydrogen, deuterium, a halogen, a cyano group, a hydroxy group, a C₁-C₃₀ alkyl group, a C₁-C₃₀ halogenated alkyl group, a C₁-C₃₀ alkoxy group, a C₃-C₃₀ cycloalkyl group, or a C₃-C₃₀ cycloalkoxy group,
n71 to n73 are each independently 1, 2, or 3,
x71 and x72 are each independently 0 or 1,
R₇₁ to R₇₃ are each independently a linear, branched, or cyclic C₁-C₃₀ monovalent hydrocarbon group that optionally includes a heteroatom,
an adjacent two of R₇₁ to R₇₃ are optionally linked to each other to form a condensed ring, and
R₇₄ to R₇₆ are each independently: hydrogen; a halogen; or a linear, branched, or cyclic C₁-C₃₀ monovalent hydrocarbon group that optionally includes a heteroatom.

16. The resist composition of claim 1, further comprising:
a quencher.

17. The resist composition of claim 16, wherein the quencher is represented by Formula 8:
B₈₁_{⁺}A₈₁⁻ Formula 8
wherein, in Formula 8,
B₈₁_{⁺} is represented by one of Formulae 8A to 8C, and A₈₁_{^{−}} is represented by one of Formulae 8D to 8F, and
B₈₁_{⁺} and A₈₁⁻ are optionally linked to each other via a carbon-carbon covalent bond: 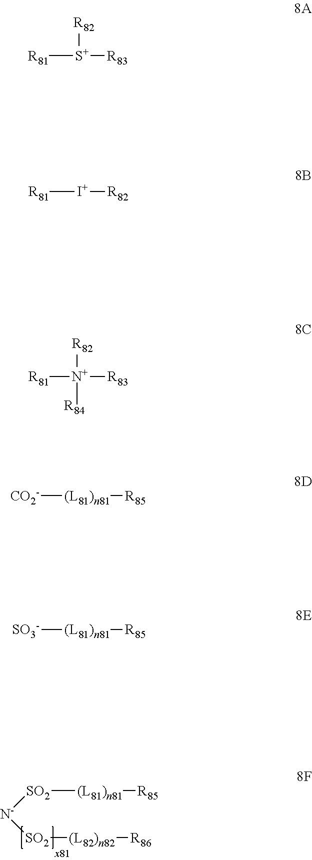
wherein, in Formulae 8A to 8F,
L₈₁ and L₈₂ are each independently a single bond or CRR′,
R and R′ are each independently hydrogen, deuterium, a halogen, a cyano group, a hydroxy group, a C₁-C₃₀ alkyl group, a C₁-C₃₀ halogenated alkyl group, a C₁-C₃₀ alkoxy group, a C₃-C₃₀ cycloalkyl group, or a C₃-C₃₀ cycloalkoxy group,
n81 and n82 are each independently 1, 2, or 3,
x81 is 0 or 1,
R₈₁ to R₈₄ are each independently a linear, branched, or cyclic C₁-C₃₀ monovalent hydrocarbon group that optionally includes a heteroatom,
an adjacent two of R₈₁ to R₈₄ are optionally linked to each other to form a condensed ring, and
R₈₅ and R₈₆ are each independently: hydrogen; a halogen; or a linear, branched, or cyclic C₁-C₃₀ monovalent hydrocarbon group that optionally includes a heteroatom.

18. A method of forming a pattern, the method comprising:
forming a resist film by applying the resist composition of claim 1 onto a substrate;
exposing at least a portion of the resist film to high-energy rays to provide an exposed resist film; and
developing the exposed resist film by using a developing solution.

19. The method of claim 18, wherein the exposing is performed by irradiating at least one of ultraviolet, deep ultraviolet (DUV), extreme ultraviolet (EUV), X rays, γ rays, electron beam (EB) rays, or α rays.

20. The method of claim 18, wherein in the exposing the at least a portion of the resist film, the polymer is ionized to generate a radical cation and an electron.
